(19) United States
(12) Patent Application Publication
(10) Pub. No.: US 2025/0246536 A1
(43) Pub. Date: Jul. 31, 2025

(54) TRENCH CAPACITOR STRUCTURE AND METHOD OF FORMING THE SAME

(71) Applicant: Taiwan Semiconductor Manufacturing Company, Ltd., Hsinchu (TW)

(72) Inventors: Shu-Hui SU, Tucheng City (TW); Hsin-Li CHENG, Hsinchu (TW); YingKit Felix TSUI, Cupertino, CA (US)

(21) Appl. No.: 18/425,306

(22) Filed: Jan. 29, 2024

(51) Int. Cl. H01L 23/522; H01L 21/768; H01L 23/00

(52) U.S. Cl. CPC H01L 23/5226; H01L 21/76805; H01L 21/76843; H01L 21/7687; H10D 1/042; H10D 1/714; H10D 1/716; H01L 24/04; H01L 24/05; H01L 24/06; H01L 24/08; H01L 24/13; H01L 2224/0401; H01L 2224/05611; H01L 2224/05639; H01L 2224/05644; H01L 2224/05647; H01L 2224/05655; H01L 2224/05657; H01L 2224/05666; H01L 2224/05676; H01L 2224/05684; H01L 2224/06181; H01L 2224/08145; H01L 2224/13021

(57) ABSTRACT

Some implementations described herein provide a semiconductor device including a trench capacitor structure and methods of forming. Using a multi-electrode connection that includes use of a conductive sidewall layer, an interconnect structure may connect with multiple, vertically-arranged electrode layers of the trench capacitor structure. In contrast to connecting with a single electrode layer, connecting with the multiple, vertically-arranged electrode layers may increase an effective thickness of a land for the interconnect structure. The increased effective thickness may reduce a likelihood of vertical interconnect access island corrosion defects developing in metal structures of the trench capacitor structure.

### BACKGROUND

A semiconductor device may include a trench capacitor region, where a multi-layer structure including layers of a conductive material interspersed with layers of a dielectric material conforms to sidewalls of a trench that penetrates vertically into a semiconductor substrate. The trench capacitor region may increase a capacitance of the semiconductor device while preserving area of the semiconductor device for integrated device structures within the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example semiconductor die package including a trench capacitor structure described herein.

FIG. 3 is a diagram of an example implementation of a trench capacitor structure described herein.

FIGS. 4A-4G are diagrams of an example implementation of forming a trench capacitor structure described herein.

FIGS. 5A-5D are diagrams of an example implementation of forming a semiconductor die described herein.

FIGS. 6A-6E are diagrams of an example implementation of forming a semiconductor die described herein.

FIGS. 7A-7G are diagrams of an example implementation of forming a portion of a semiconductor die package described herein.

FIGS. 8A and 8B are diagrams of data related to vertical interconnect access induced metal corrosion defects described herein.

FIG. 9 is a diagram of example components of a device described herein.

FIG. 10 is a flowchart of an example process associated with forming a trench capacitor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Performance improvements to a trench capacitor structure (e.g., increased amounts of charge storage, increased durations of charge storage) may be achieved by increasing a density of capacitor electrode layers (e.g., layers of a conductive material) and capacitor dielectric layers (e.g., layers of dielectric material) that form the trench capacitor structure. Increasing the density may include increasing a quantity of the capacitor electrode layers and/or the capacitor dielectric layers within a given area of a semiconductor device including the trench capacitor structure.

In some cases, increasing the density of the trench capacitor structure may exceed a spacing limitation (e.g., process capabilities of lithography tools and/or etching tools) for interconnect structures that connect with the capacitor electrode layers. Exceeding the spacing limitation may cause an increase in a size of a semiconductor device including the trench capacitor structure. Additionally, or alternatively and in some cases, increasing the density of the trench capacitor structure may reduce a thickness of the capacitor electrode layers to cause a reduction in a process window for a cleaning operation used to form the trench capacitor structure. Reducing the process window may cause an increase in a likelihood of formation of vertical interconnect access induced metal island corrosion (VIMIC) defects to metal structures included in the trench capacitor structure. The increased likelihood of the VIMIC defects may reduce a manufacturing yield and/or a reliability of the semiconductor device.

Some implementations described herein provide a semiconductor device including a trench capacitor structure and methods of forming. Using a multi-electrode connection that includes use of a conductive sidewall layer, the interconnect structure may connect with multiple, vertically-arranged electrode layers of the trench capacitor structure. In contrast to connecting with a single electrode layer, connecting with the multiple, vertically-arranged electrode layers may increase an effective thickness of a land for the interconnect structure. The increased effective thickness may increase an etching and cleaning process window to reduce a likelihood of VIMIC defects developing in metal structures of the trench capacitor structure.

In this way, a performance of the trench capacitor structure (e.g., an amount of charge storage and/or a duration of the charge storage) is increased while improving a quality and/or a reliability of the semiconductor device. Additionally, a quantity of interconnect structures for the trench capacitor structure is decreased to reduce a size of the trench capacitor structure (thereby reducing a size of the semiconductor device). By increasing the performance of the trench capacitor structure, improving the yield and/or reliability of the semiconductor device, or reducing the size of the semiconductor device, an amount of resources used to support a market consuming the semiconductor device (e.g., an amount of semiconductor processing tools, labor, raw materials, and/or computing resources) may be reduced.

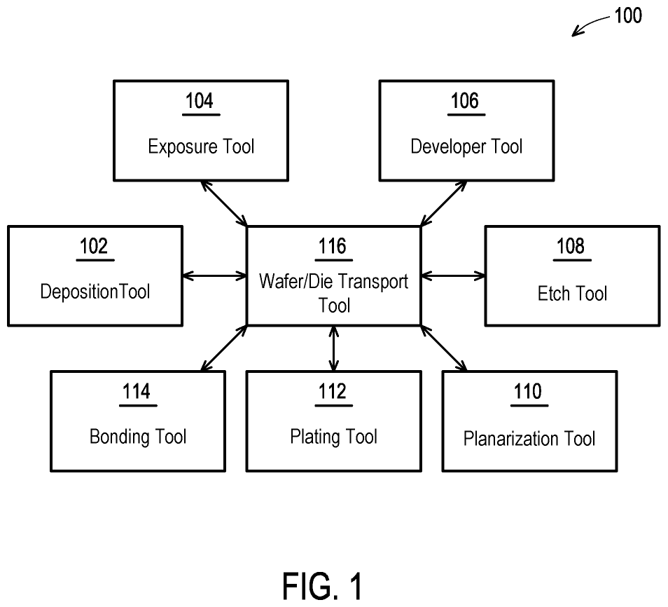

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 may be a direct bonding tool that is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

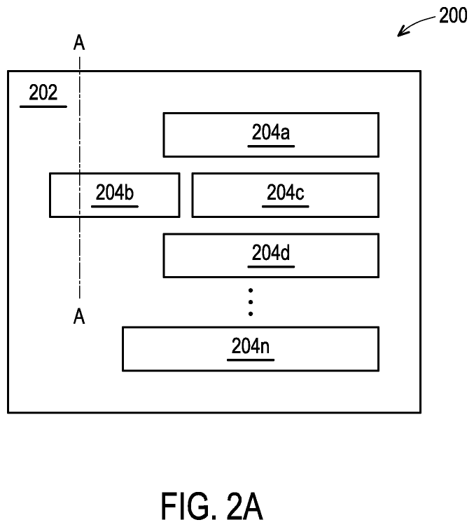

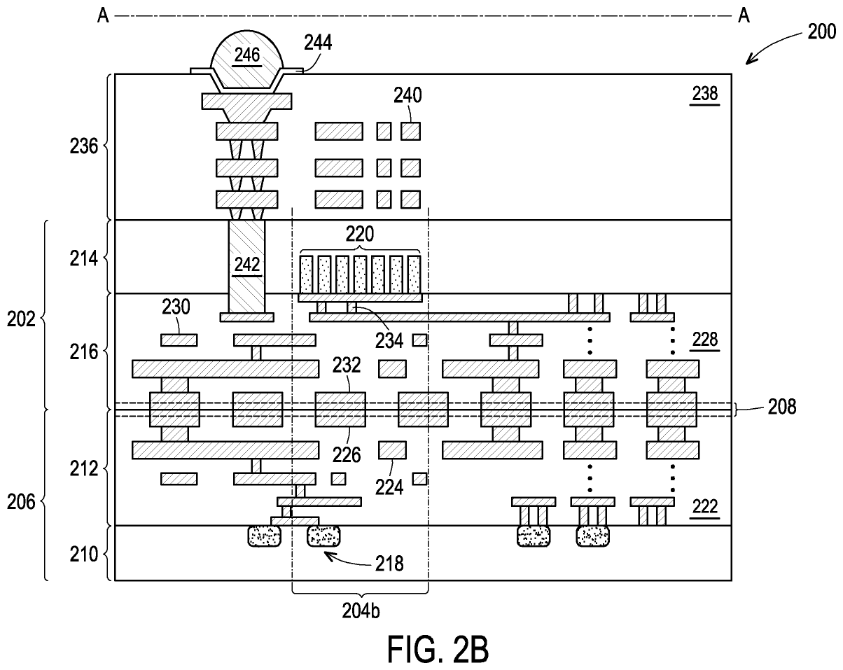

In some implementations, and as described in greater detail in connection with FIGS. 2A-10, one or more of the semiconductor processing tools 102-114 and/or the wafer/die transport tool 116 may be used to perform a series of semiconductor processing operations. The series of semiconductor processing operations includes forming, on a substrate, a layer stack of a trench capacitor structure that includes a first capacitor electrode layer, a capacitor dielectric layer on the first capacitor electrode layer, and a second capacitor electrode layer over the first capacitor electrode layer. The series of semiconductor processing operations includes forming one or more dielectric layers above the layer stack. The series of semiconductor processing operations includes forming a cavity that penetrates through the one or more dielectric layers, through the second capacitor electrode layer, through the capacitor dielectric layer, and into the first capacitor electrode layer. The series of semiconductor processing operations includes forming a multi-electrode connection using the cavity.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may be used to perform one or more functions described as being performed by another set of devices of the example environment 100.

FIGS. 2A and 2B are diagrams of an example semiconductor die package 200 including a trench capacitor structure described herein. The semiconductor die package 200 includes an example of a wafer on wafer (WoW) semiconductor die package, a die on wafer semiconductor die package, a die-on-die semiconductor die package, or another type of semiconductor die package in which semiconductor dies are directly bonded and vertically arranged or stacked. FIG. 2A illustrates a top-down view of a portion of the semiconductor die package 200, including a reference section line A-A used in connection with FIG. 2B.

As shown in FIG. 2A, the semiconductor die package 200 may include a first semiconductor die 202 and a plurality of trench capacitor regions 204a-204n in the first semiconductor die 202. The trench capacitor regions 204a-204n may be horizontally arranged in the first semiconductor die 202. The trench capacitor regions 204a-204n may include various sizes and/or shapes to provide a sufficient amount of decoupling capacitance across the semiconductor die package 200 for the circuits and semiconductor devices of the semiconductor die package 200.

As shown in FIG. 2B (e.g., a section view along A-A of FIG. 2A), the semiconductor die package 200 includes the first semiconductor die 202 and a second semiconductor die 206. In some implementations, the semiconductor die package 200 includes additional semiconductor dies. The first semiconductor die 202 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally, and/or alternatively, the first semiconductor die 202 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The second semiconductor die 206 may include the same type of semiconductor die as the first semiconductor die 202, or may include a different type of semiconductor die.

The first semiconductor die 202 and the second semiconductor die 206 may be bonded together (e.g., directly bonded) at a bonding interface 208. In some implementations, one or more layers may be included between the first semiconductor die 202 and the second semiconductor die 206 at the bonding interface 208, such as one or more passivation layers, one or more bonding films, and/or one or more layers of another type.

The second semiconductor die 206 may include a device region 210 and an interconnect region 212 adjacent to and/or above the device region 210. In some implementations, the second semiconductor die 206 may include additional regions. Similarly, the first semiconductor die 202 may include a device region 214 and an interconnect region 216 adjacent to and/or below the device region 214. In some implementations, the first semiconductor die 202 may include additional regions. The first semiconductor die 202 and the second semiconductor die 206 may be bonded at the interconnect region 212 and the interconnect region 216. The bonding interface 208 may be located at a first side of the interconnect region 216 facing the interconnect region 212 and corresponding to a first side of the second semiconductor die 206.

The device regions 210 and 214 may each include a semiconductor substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The device region 210 of the second semiconductor die 206 may include one or more semiconductor devices 218 included in the semiconductor substrate of the device region 210. The semiconductor devices 218 may include one or more transistors (e.g., planar transistors, fin field effect transistors (FinFETs), nanosheet transistors (e.g., gate all around (GAA) transistors), memory cells, capacitors, inductors, resistors, pixel sensors, circuits (e.g., integrated circuits (ICs)), and/or another type of semiconductor devices. In some implementations, the device region 210 includes logic circuitry.

As further shown in FIG. 2B, the device region 214 of the first semiconductor die 202 (e.g., an IC device) may include a trench capacitor structure 220 in the semiconductor substrate of the device region 214 (e.g., within the trench capacitor region 204b of FIG. 2A). A depth of the trench capacitor structure 220 may be selected to provide sufficient capacitance so as to satisfy circuit decoupling parameters for the semiconductor devices 218 included in circuits of the semiconductor die package 200, while reducing the likelihood of warping, breaking, and/or cracking of the semiconductor die package 200. Some of the circuits of the semiconductor die package 200 may have greater decoupling capacitance requirements than other circuits in order to properly operate at desired performance parameters. Accordingly, deeper trench capacitor structures may be formed for these circuits relative to the depth of trench capacitor structures that are formed for other circuits that have lesser decoupling capacitance requirements. This enables a balance between satisfying capacitance requirements in the semiconductor die package 200.

In some implementations, the interconnect regions 212 and 216 are referred to as back end of line (BEOL) regions. The interconnect region 212 may include one or more dielectric layers 222, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the dielectric layer(s) 222. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 212 may further include one or more metallization layer(s) 224 in the dielectric layer(s) 222. The semiconductor devices 218 in the device region 210 may be electrically connected and/or physically connected with one or more of the metallization layer(s) 224. The metallization layer(s) 224 may include conductive lines, trenches, vias, pillars, interconnects, and/or another type of metallization layers. Contacts 226 may be included in the dielectric layer(s) 222 of the interconnect region 212. The contact(s) 226 may be electrically connected and/or physically connected with one or more of the metallization layer(s) 224. The contact(s) 226 may include conductive terminals, conductive pads, conductive pillars, under bump metallization (UBM) structures, and/or another type of contacts. The metallization layer(s) 224 and the contact(s) 226 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 216 may include one or more dielectric layers 228, which may include a silicon nitride (SiNₓ), an oxide (e.g., a silicon oxide (SiOₓ) and/or another oxide material), a low dielectric constant (low-k) dielectric material, an undoped silicate glass (USG), and/or another type of dielectric material. In some implementations, one or more etch stop layers (ESLs) may be included in between layers of the dielectric layer(s) 228. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 216 may further include one or more metallization layers 230 in the dielectric layer(s) 228. The trench capacitor structure 220a-220c in the device region 214 may be electrically connected and/or physically connected with one or more of the metallization layer(s) 230. The metallization layer(s) 230 may include conductive lines, trenches, vias, pillars, interconnects, and/or another type of metallization layers. Contacts 232 may be included in the dielectric layer(s) 228 of the interconnect region 216. The contact(s) 232 may be electrically connected and/or physically connected with one or more of the metallization layer(s) 230. Moreover, the contact(s) 232 may be electrically and/or physically connected with the contact(s) 226 of the second semiconductor die 206. The contact(s) 232 may include conductive terminals, conductive pads, conductive pillars, UBM structures, and/or another type of contacts. The metallization layer(s) 230 and the contact(s) 232 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 216 may include one or more interconnect structures 234. The interconnect structure(s) 234 (e.g., vertical interconnect access structures, or vias) may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials. The interconnect structure(s) 234 may provide an electrical connection between one or more of the metallization layer(s) 230. Additionally, or alternatively, the interconnect structure(s) 234 may connect the trench capacitor structure 220 to a metallization layer of the one or more metallization layers.

As further shown in FIG. 2B, the semiconductor die package 200 may include a redistribution structure 236. The redistribution structure 236 may include a redistribution layer (RDL) structure, an interposer, a silicon-based interposer, a polymer-based interposer, and/or another type of redistribution structure. The redistribution structure 236 may be configured to fan out and/or route signals and I/O of the semiconductor dies 202 and 206.

The redistribution structure 236 may include one or more dielectric layers 238 and a plurality of metallization layers 240 disposed in the one or more dielectric layers 238. The dielectric layer(s) 238 may include polybenzoxazole (PBO), a polyimide, a low temperature polyimide (LTPI), an epoxy resin, an acrylic reason, a phenol resin, benzocyclobutene (BCB), one or more dielectric layers, and/or another suitable dielectric material.

The metallization layers 240 of the redistribution structure 236 may include one or more materials such as a gold (Au) material, a copper (Cu) material, a silver (Ag) material, a nickel (Ni) material, a tin (Sn) material, and/or a palladium (Pd) material, among other examples. The metallization layers 240 of the redistribution structure 236 may include metal lines, vias, interconnects, and/or another type of metallization layers.

As further shown in FIG. 2B, the semiconductor die package 200 may include one or more backside through silicon via (BTSV) structures 242 through the device region 214, and into a portion of the interconnect region 216 of the first semiconductor die 202. The BTSV structure(s) 242 may include vertically elongated conductive structures (e.g., conductive pillars, conductive vias) that electrically connect one or more of the metallization layer(s) 230 in the interconnect region 216 of the first semiconductor die 202 to one or more metallization layers 240 in the redistribution structure 236. The BTSV structures 242 may be referred to as through silicon via (TSV) structures in that the BTSV structures 242 extend fully through a semiconductor substrate (e.g., a silicon substrate) of the device region 214 as opposed to extending fully through a dielectric layer or an insulator layer. The BTSV structure(s) 242 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

UBM layers 244 may be included on a top surface of the one or more dielectric layers 238. The UBM layers 244 may be electrically connected and/or physically connected with one or more metallization layers 240 in the redistribution structure 236. The UBM layers 244 may be included in recesses in the top surface of the one or more dielectric layers 238. The UBM layers 244 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

As further shown in FIG. 2B, the semiconductor die package 200 may include conductive terminals 246. The conductive terminals 246 may be electrically connected and/or physically connected with the UBM layers 244. The UBM layers 244 may be included to facilitate adhesion to the one or more metallization layers 240 in the redistribution structure 236, and/or to provide increased structural rigidity for the conductive terminals 246 (e.g., by increasing the surface area to which the conductive terminals 246 are connected). The conductive terminals 246 may include ball grid array (BGA) balls, land grid array (LGA) pads, pin grid array (PGA) pins, and/or another type of conductive terminals. The conductive terminals 246 may enable the semiconductor die package 200 to be mounted to a circuit board, a socket (e.g., an LGA socket), an interposer or redistribution structure of a semiconductor device package (e.g., a chip on wafer on substrate CoWoS package, an integrated fanout (InFO) package), and/or another type of mounting structure.

As indicated above, FIGS. 2A and 2B are provided as an example. Other examples may differ from what is described with regard to FIGS. 2A and 2B.

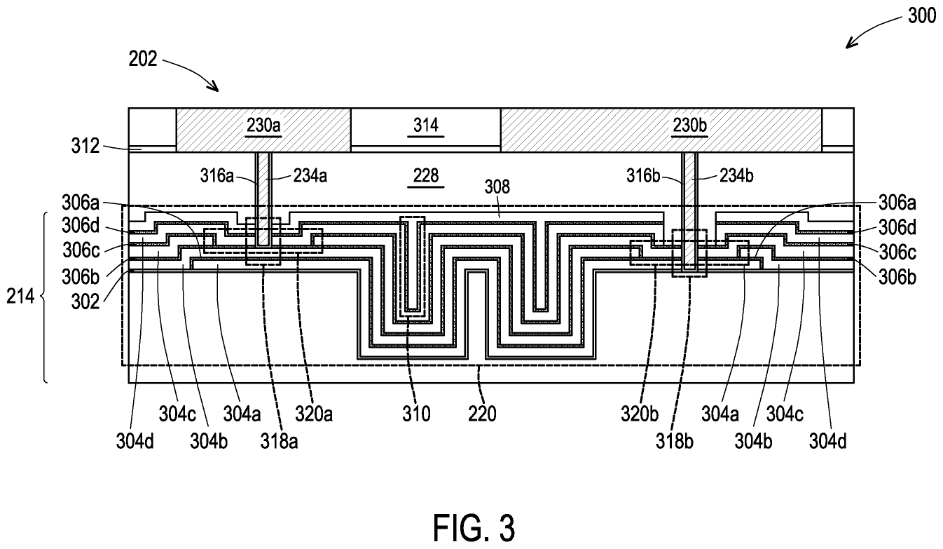

FIG. 3 is a diagram of an example implementation 300 of a trench capacitor structure described herein. The trench capacitor structure may correspond to the trench capacitor structure 220 of FIG. 2B that is included in the substrate of the device region 214 of the semiconductor die 202 of FIG. 2B.

As shown in FIG. 3, and in some implementations, the trench capacitor structure 220 is a multi-layer structure (e.g., a layer stack). In such implementations, the trench capacitor structure 220 may include a liner layer 302 (e.g., a “glue” layer”) lining trenches in the substrate of the device region 214. The liner layer 302 may include a dielectric material, such as a silicon oxide material (SiO₂) or a silicon nitride material (SiN), among other examples.

The trench capacitor structure 220 may further include a layer stack that includes one or more conductive layers 304 (e.g., capacitor electrode layers) and one or more dielectric layers 306 (e.g., capacitor dielectric layers). The conductive layer(s) 304 and the dielectric layer(s) 306 may be vertically-arranged and interspersed with one another using an alternating and/or a staggering configuration within the trench capacitor structure 220.

The conductive layer(s) 304 may include one or more conductive materials, such as a conductive metal (e.g., copper (Cu), tungsten (W), titanium (Ti), tantalum (Ta), ruthenium (Ru), cobalt (Co)), a conductive ceramic (e.g., tantalum nitride (TaN), titanium nitride (TiN)), and/or another type of conductive material. The dielectric layer(s) 306 may include one or more dielectric materials such as an oxide (e.g., silicon oxide (SiOₓ)), a nitride (e.g., silicon nitride (SiₓN_{y}), and/or another suitable dielectric material.

As shown in FIG. 3, the conductive layer(s) 304 include the conductive layer 304a (e.g., a negative (−) polarity capacitor electrode layer of the trench capacitor structure 220), the conductive layer 304b (e.g., a positive (+) polarity capacitor electrode layer of the trench capacitor structure 220), the conductive layer 304c (e.g., a negative (−) polarity capacitor electrode layer of the trench capacitor structure 220), and the conductive layer 304d (e.g., a positive (+) polarity capacitor electrode layer of the trench capacitor structure 220).

As shown in FIG. 3, the dielectric layer 306a is between (e.g., interspersed with) the conductive layer 304a and the conductive layer 304b. Additionally, or alternatively, the dielectric layer 306b is between (e.g., interspersed with) the conductive layer 304b and the conductive layer 304c. Additionally, or alternatively, the dielectric layer 306c is between (e.g., interspersed with) the conductive layer 304c and the conductive layer 304d.

As shown in FIG. 3, the trench capacitor structure 220 includes a dielectric layer 308 (e.g., a “merged” layer). The dielectric layer 308 may include an oxide material such as aluminum oxide material (Al₂O₃), a zirconium oxide material (ZrO₂), or a silicon dioxide material (SiO₂), among other examples. In FIG. 3, the dielectric layer 308 merges in a vertically-oriented merge region 310 between co-facing surfaces of a top layer of the trench capacitor structure the conductive layer 304d.

In some implementations, one or more additional dielectric layers are above the trench capacitor structure 220. For example, and in addition to the dielectric layer(s) 228 described in connection with FIG. 2B, a dielectric layer 312, such as a silicon nitride (SiN) material, and a dielectric layer 314, such as an undoped silicon glass (USG) material, may be above the trench capacitor structure 220, among other examples.

As shown in FIG. 3, the metallization layer(s) 230 (e.g., the metallization layer 230a and the metallization layer 230b) are surrounded by the dielectric layers 312 and 314. In some implementations, the metallization layer(s) 230 connect to the trench capacitor structure 220 using the interconnect structure(s) 234 (e.g., the interconnect structure 234a and/or the interconnect structure 234b), where the interconnect structure(s) 234 are surrounded by one or more sidewall layers 316 (e.g., the sidewall layer 316a and/or the sidewall layer 316b).

In some implementations, the sidewall layer(s) 316 perform as stress buffering layers (e.g., absorb stresses and/or strains within the trench capacitor structure 220 during formation of the trench capacitor structure 220), and may prevent delamination of the conductive layer(s) 304 and/or the dielectric layer(s) 306.

Additionally, or alternatively and in some implementations, the sidewall layer(s) 316 electrically couple two or more of the conductive layer(s) 304 and/or electrically couple two or more of the conductive layer(s) 304 with a substrate of the device region 214. In such cases, the sidewall layer(s) 316 may include a conductive material such as a titanium nitride material (TiN) or tantalum nitride material (TaN), among other examples. In a case in which the interconnect structure(s) 234 include a copper material (Cu), the sidewall layer(s) 316 may perform as copper barrier layers.

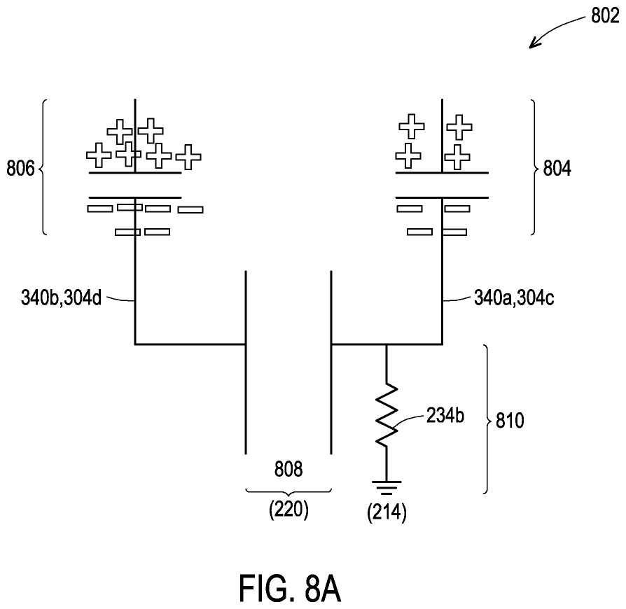

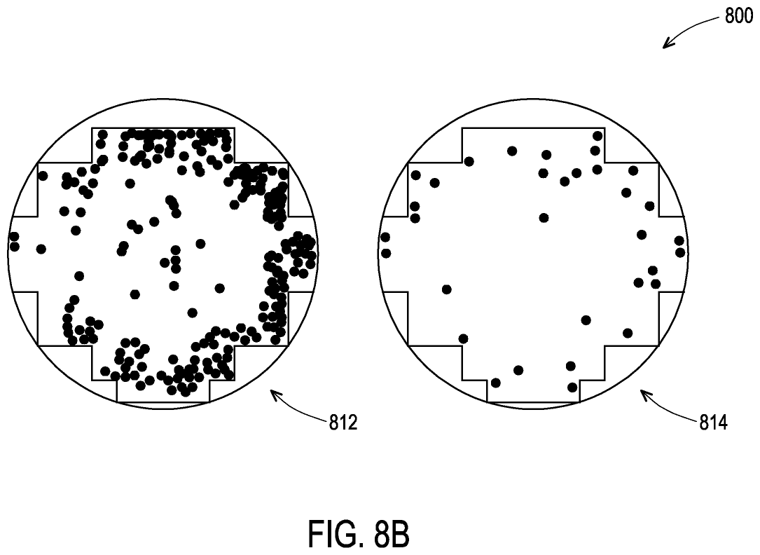

The interconnect structure(s) 234 and the sidewall layer(s) 316 connect the metallization layer(s) 230 with the trench capacitor structure 220. Connecting the metallization layer(s) 230 with the trench capacitor structure 220 may include using or more multi-electrode connections 318 (e.g., the multi-electrode connection 318a and/or the multi-electrode connection 318b) to connect with two or more conductive layers (e.g., two or more capacitor electrode layers) having a same polarity. As described in greater detail in connection with FIGS. 8A and 8B, use of the multi-electrode connection(s) 318 may increase an effective thickness of a land for the interconnect structure(s) 234. The increased effective thickness (e.g., a combined thickness of like-polarity conductive layers) may increase an etching and cleaning process window to reduce a likelihood of VIMIC defects developing during formation of the trench capacitor structure 220.

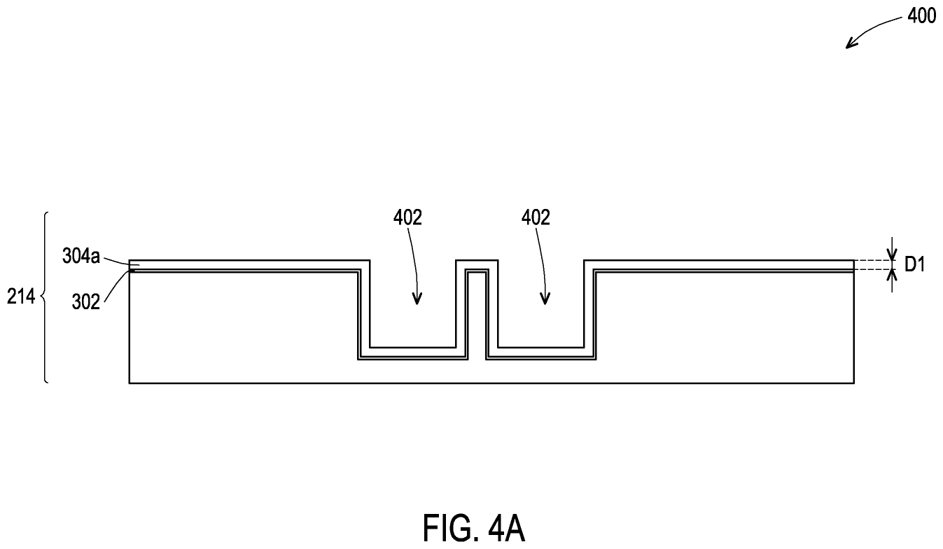

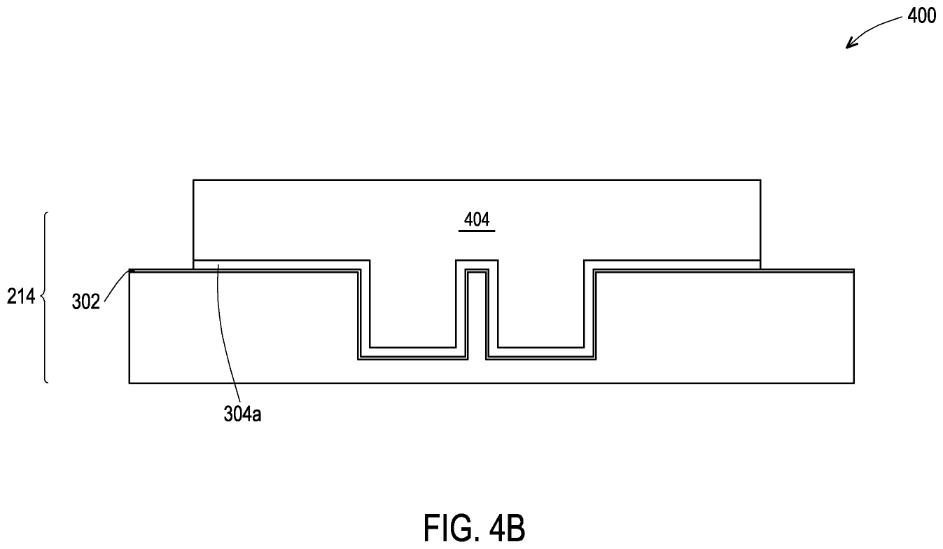

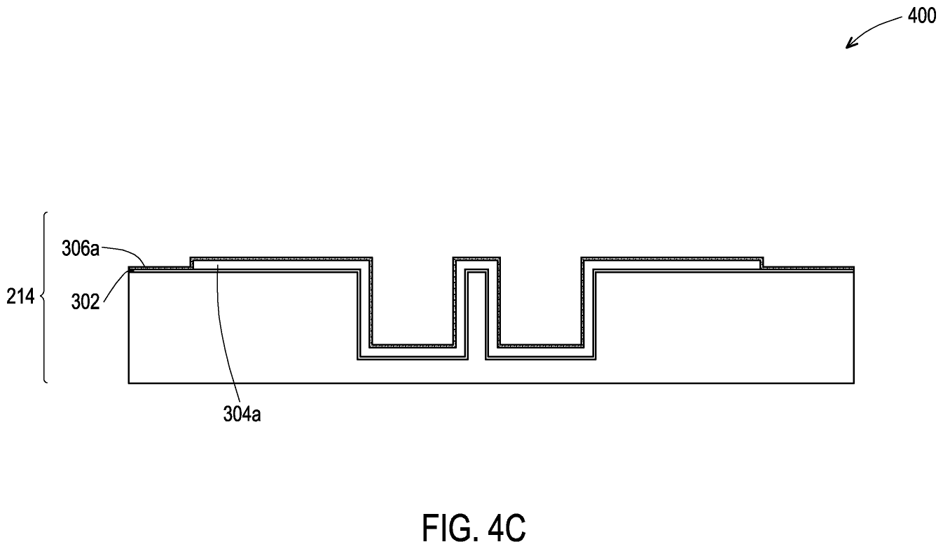

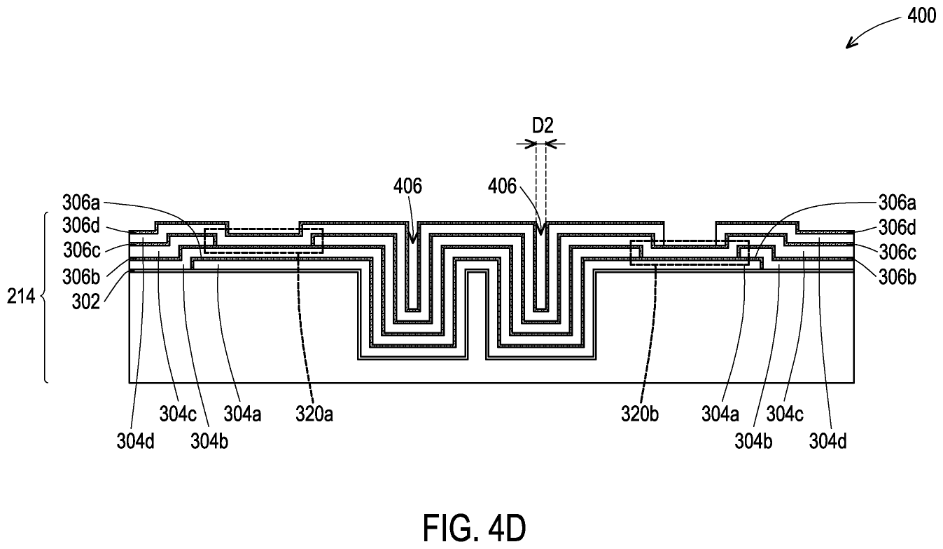

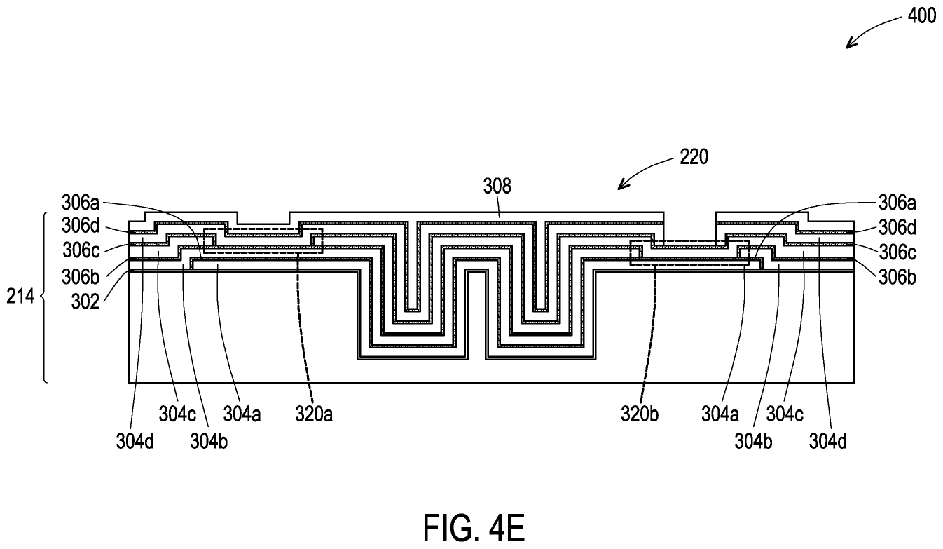

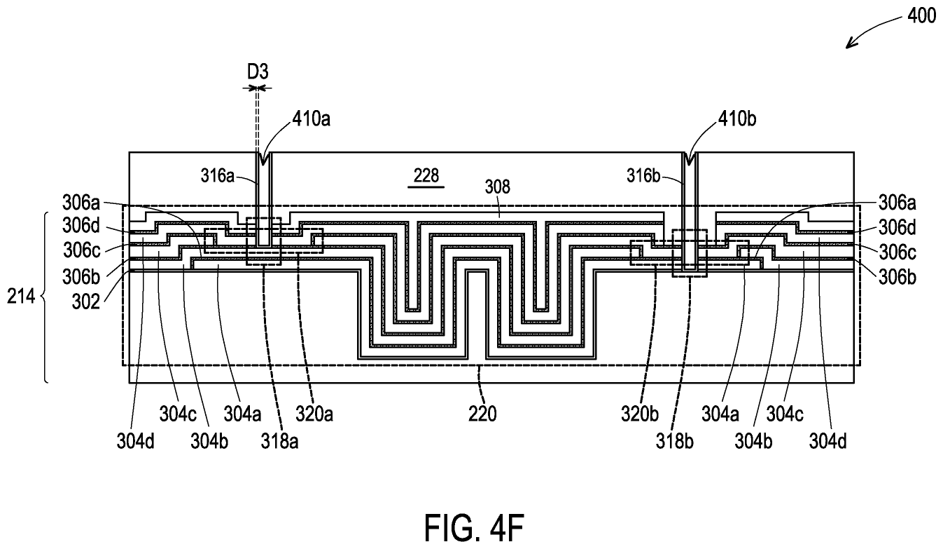

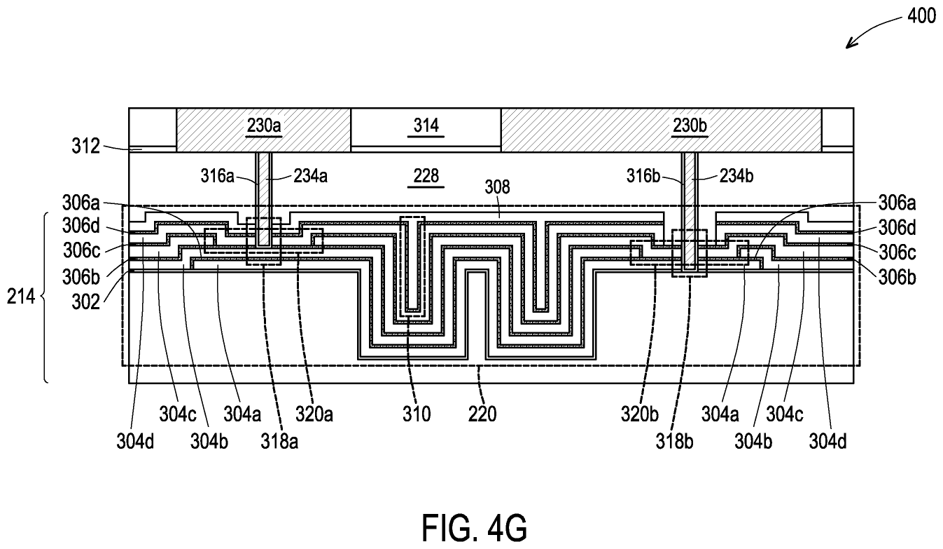

To accommodate the multi-electrode connection(s) 318, and as described in greater detail in connection with FIGS. 4A-4G, forming the conductive layer(s) 304 may include forming one or more gap region(s) 320 in one or more of the conductive layer(s) 304 (e.g., the gap region 320a corresponding to a discontinuity in the conductive layer 304c and/or the gap region 320b corresponding to a discontinuity in the conductive layer 304b). Furthermore, one or more of the dielectric layer(s) 306 may conform with edges of the gap region(s) 320 to isolate one or more of the conductive layer(s) 304.

Based on a selected configuration, the interconnect structure(s) 234 and the sidewall layer(s) 316 may penetrate through one or more dielectric above the gap region(s) 320. Additionally, or alternatively, the interconnect structure(s) 234 and the sidewall layer(s) 316 may penetrate through portions of one or more conductive layers filling the gap region(s) 320. Additionally, or alternatively, the interconnect structure(s) 234 and the sidewall layer(s) 316 may penetrate through one or more dielectric layer(s) 306 on a conductive layer below the gap region(s) 320. Additionally, or alternatively, the interconnect structure(s) 234 and the sidewall layer(s) 316 may penetrate into and/or through conductive layers below the gap region(s) 320. Additionally, or alternatively, the interconnect structure(s) 234 and the sidewall layer(s) 316 may penetrate into the substrate of the device region 214.

As an example, and as shown in FIG. 3, the metallization layer 230a connects with the conductive layer 304b and the conductive layer 304d (e.g., connects with multiple, positive (+) polarity capacitor electrode layers) using the multi-electrode connection 318a. As such, the multi-electrode connection 318a includes the interconnect structure 234a and the sidewall layer 316a. Furthermore, the interconnect structure 234a and the sidewall layer 316a penetrate through the dielectric layer(s) 228, through the dielectric layer 308, through the dielectric layer 306d, through a portion of the conductive layer 304d that is in the gap region 320a, through the dielectric layer 306c and/or dielectric layer 306b (e.g., the dielectric layer 306c and dielectric layer 306b may merge on the conductive layer 304b), and into the conductive layer 304b.

Additionally, or alternatively and as shown in FIG. 3, the metallization layer 230b connects with the conductive layer 304a and the conductive layer 304c (e.g., connects with multiple, negative (−) polarity capacitor electrode layers) using the multi-electrode connection 318b. As such, the multi-electrode connection 318b includes the interconnect structure 234b and the sidewall layer 316b. Furthermore, the interconnect structure 234b and the sidewall layer 316b penetrate through the dielectric layer(s) 228, through the dielectric layer 306c, through a portion of the conductive layer 304c that is in the gap region 320b, through the dielectric layer 306b and/or dielectric layer 306a (e.g., the dielectric layer 306b and the dielectric layer 306a may merge on the conductive layer 304a), through the conductive layer 304a, and into the substrate of the device region 214.

As indicated above, FIG. 3 is provided as an example. Other examples may differ from what is described with regard to FIG. 3.

As described in connection with FIGS. 2A, 2B, and 3, and in some implementations, a structure (e.g., the trench capacitor structure 220) includes a first conductive layer (e.g., the conductive layer 304b). The structure includes a dielectric layer (e.g., the dielectric layer 306b) on the first conductive layer. The structure includes a second conductive layer (e.g., the conductive layer 304c) on the dielectric layer having a gap region (e.g., the gap region 320a) over a portion of the first conductive layer. The structure includes a third conductive layer (e.g., the conductive layer 304c) including a portion in the gap region. The structure includes an interconnect structure (e.g., the interconnect structure 234a) penetrating through the portion of the third conductive layer in the gap region, through the dielectric layer, and into the first conductive layer. The structure includes a sidewall layer (e.g., the sidewall layer 316a) surrounding the interconnect structure and penetrating through the portion of the third conductive layer in the gap region, through the dielectric layer, and into the first conductive layer.

Additionally, or alternatively and in some implementations, a semiconductor device (e.g., the semiconductor die package 200 including the semiconductor die 202) includes a metallization layer that includes a first portion (e.g., the metallization layer 230a) and a second portion (e.g., the metallization layer 230b). The semiconductor device includes a trench capacitor structure (e.g., the trench capacitor structure 220) that includes at least two vertically-arranged positive polarity capacitor electrode layers (e.g., the conductive layer 304b and the conductive layer 304d) and least two vertically-arranged negative polarity capacitor electrode layers (e.g., the conductive layer 304a and conductive layer 304c). The semiconductor device includes a first interconnect structure (e.g., the interconnect structure 234a) connecting the at least two vertically-arranged positive polarity capacitor electrode layers with the first portion. The semiconductor device includes a second interconnect structure (e.g., the interconnect structure 234b) connecting the at least two vertically-arranged negative polarity capacitor electrode layers with the second portion.

In these ways, a performance of a trench capacitor structure is increased (e.g., an amount of charge storage and/or a duration of the charge storage is increased by increasing a density of capacitor electrode layers and/or capacitor dielectric layers) while improving a quality and/or a reliability of a semiconductor device that includes the trench capacitor structure (e.g., reducing VIMIC defects in the semiconductor device improves the quality and/or reliability of the semiconductor device). Additionally, a quantity of interconnect structures for the trench capacitor structure is decreased (e.g., a single interconnect structure may connect to two or more capacitor electrode layers) to reduce a size of the trench capacitor structure, thereby reducing a size of the semiconductor device. By increasing the performance of the trench capacitor structure, improving the yield and/or reliability of the semiconductor device, or reducing the size of the semiconductor device, an amount of resources used to support a market consuming the semiconductor device (e.g., an amount of semiconductor processing tools, labor, raw materials, and/or computing resources) may be reduced.

FIGS. 4A-4G are diagrams of an example implementation 400 for forming a trench capacitor structure described herein. The trench capacitor structure may correspond to the trench capacitor structure 220. Furthermore, implementation 400 may include one or more semiconductor processing operations performed by one or more of the semiconductor processing tools 102-114 described in connection with FIG. 1.

As shown in FIG. 4A, and as part of implementation 400, cavities 402 are formed in a substrate of the device region 214. In some implementations, a pattern in a photoresist layer is used to etch the substrate to form the cavities 402. In these implementations, a deposition tool 102 may be used to form the photoresist layer on the substrate. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the substrate based on the pattern to form the cavities 402. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate based on a pattern.

Further, and as shown in FIG. 4A, the liner layer 302 is formed over and/or on the substrate of the device region 214 and in the cavities 402. A deposition tool 102 may be used to deposit the liner layer 302 using a CVD technique, a PVD technique, an ALD technique, an oxidation technique, or another deposition technique described above in connection with FIG. 1, and/or another suitable deposition technique. The liner layer 302 may be deposited in one or more deposition operations. In some implementations, a planarization tool 110 may be used to planarize the liner layer 302 and/or the liner layer 302 is deposited.

Further, and as shown in FIG. 4A, the conductive layer 304a is formed over and/or on the liner layer 302. A deposition tool 102 and/or a plating tool 112 may be used to deposit the conductive layer 304a using a CVD technique, a PVD technique, an ALD technique, an electroplating technique, another deposition technique described above in connection with FIG. 1, and/or another suitable deposition technique. The conductive layer 304a may be deposited in one or more deposition operations. In some implementations, a seed layer is first deposited, and the conductive layer 304a is deposited on the seed layer. In some implementations, a planarization tool 110 may be used to planarize the conductive layer 304a after the conductive layer 304a is deposited.

A thickness D1 of the conductive layer 304a (and/or subsequently formed conductive layers) may be included in a range of approximately 100 angstroms to approximately 200 angstroms. If the thickness D1 is less than approximately 100 angstroms, an equivalent series resistance of a trench capacitor structure including the conductive layer 304a may increase and cause an effective capacitance of the trench capacitor structure to not satisfy a performance threshold. If the thickness D1 is in the range of approximately 100 angstroms to approximately 200 angstroms, the effective capacitance of the trench capacitor structure may satisfy the performance threshold and/or a size of the trench capacitor structure may satisfy a layout threshold (e.g., a size requirement). If the thickness D1 is greater than approximately 200 angstroms, a size of the trench capacitor structure may increase to not satisfy the layout threshold. However, other values and ranges for the thickness D1 are within the scope of the present disclosure.

As shown in FIG. 4B, and as part of implementation 400, portions of the conductive layer 304a are removed to expose the liner layer 302. To remove the portions, a deposition tool 102 may be used to deposit a photoresist layer 404 over and/or on the conductive layer 304a. An exposure tool 104 may be used to expose the photoresist layer 404 to a radiation source to pattern the photoresist layer 404. A developer tool 106 may be used to develop and remove portions of the photoresist layer 404 to expose the pattern (e.g., the portions of the conductive layer 304a that are removed). An etch tool 108 may be used to etch the portions and expose the liner layer 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the portions based on a pattern.

As shown in FIG. 4C, and as part of implementation 400, the dielectric layer 306a is formed over and/or on the conductive layer 304a and portions of the liner layer 302 (e.g., portions of the liner layer 302 exposed by semiconductor operations described in connection with FIG. 4B). In some implementations, a deposition tool 102 may be used to deposit the dielectric layer 306a using an ALD technique. Alternatively, a deposition tool may be used to deposit the dielectric layer 306a using a PVD technique, a CVD technique, an oxidation technique, another type of deposition technique described in connection with FIG. 1, and/or another suitable deposition technique. The dielectric layer 306a may be deposited in one or more deposition operations. In some implementations, a planarization tool 110 may be used to planarize the dielectric layer 306a after the dielectric layer 306a is deposited.

As shown in FIG. 4D, and as part of implementation 400, additional conductive layers 304b-304d and additional dielectric layers 306c and 306d are formed. Forming the additional conductive layers 304b-304d and/or the additional dielectric layers 306c and 306d may include iterating one or more semiconductor processing operations as described in connection with FIGS. 4A-4C. Furthermore, forming the conductive layers 304b-304d includes forming the gap region 320a (e.g., a discontinuity between edges of the conductive layer 304c may define the gap region 320a) and the gap region 320b (e.g., a discontinuity between edges of the conductive layer 304b may define the gap region 320b).

As shown in FIG. 4D, and after formation of the dielectric layer 306d, gaps 406 having a width D2 exist between co-facing surfaces of the dielectric layer 306d. In some implementations, the width D2 is greater than approximately 10 nanometer (nm). If the width D2 is greater than approximately 10 nm, filling of the gaps 406 with photoresist during a subsequent patterning operation will not be inhibited by outgassing that may cause bubbles in the photoresist and cause manufacturing defects. If the width D2 is less than approximately 10 nm, filling of the gaps 406 with photoresist during the subsequent patterning operation may be inhibited by outgassing and bubbles may form in the photoresist to cause manufacturing defects. Further, and although shown between co-facing surfaces of a top layer that is a top capacitor dielectric layer, in other implementations, the gaps 406 may be between surfaces of a top layer that is a top capacitor electrode layer.

As shown in FIG. 4E, and as part of implementation 400, the dielectric layer 308 is formed on and/or over the dielectric layer 306d. A deposition tool 102 may be used to deposit the 306d using a PVD technique, an ALD technique, a CVD technique, an oxidation technique, another type of deposition technique described in connection with FIG. 1, and/or another suitable deposition technique. The dielectric layer 306d may be deposited in one or more deposition operations. In some implementations, a planarization tool 110 may be used to planarize the 306d after the dielectric layer 306d is deposited.

As shown in FIG. 4F, and as part of implementation 400, the dielectric layer(s) 228 are formed over and/or on the dielectric layer 308. A deposition tool 102 may be used to deposit the dielectric layer(s) 228 using a PVD technique, an ALD technique, a CVD technique, an oxidation technique, another type of deposition technique described in connection with FIG. 1, and/or another suitable deposition technique. The dielectric layer(s) 228 may be deposited in one or more deposition operations. In some implementations, a planarization tool 110 may be used to planarize the dielectric layer(s) 228 after deposition.

As further shown in FIG. 4F, a cavity 410a is formed through the dielectric layer(s) 228, through the dielectric layer 308, through the dielectric layer 306d, through a portion of the conductive layer 304d that is in the gap region 320a, through the dielectric layer 306c and/or dielectric layer 306b (e.g., the dielectric layer 306c and dielectric layer 306b may merge on the conductive layer 304b), and into the conductive layer 304b. Furthermore, a cavity 410b is formed through the dielectric layer(s) 228, through the dielectric layer 306c, through a portion of the conductive layer 304c that is in the gap region 320b, through the dielectric layer 306b and/or dielectric layer 306a (e.g., the dielectric layer 306b and the dielectric layer 306a may merge on the conductive layer 304a), through the conductive layer 304a, and into the substrate of the device region 214.

In some implementations, a pattern in a photoresist layer is used to etch the dielectric layer(s) 228, the dielectric layer 308, dielectric layers 306a-306d, the conductive layers conductive layer 304a-304d, an/or the substrate of the device region 214 to form the cavities 410a and 410b. In these implementations, the deposition tool 102 may be used to form the photoresist layer over and/or on the dielectric layer(s) 228. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer(s) 228, the dielectric layer 308, dielectric layers 306a-306d, the conductive layer 304a-304d, and/or the substrate to form the cavities 410a and 410b based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer(s) 228, the dielectric layer 308, dielectric layers 306a-306d, the conductive layer 304a-304d, and/or the substrate based on a pattern.

Further, and as shown in FIG. 4F, the sidewall layer 316a is formed on surfaces of the cavity 410a and the sidewall layer 316b is formed on surfaces of the cavity 410b. A deposition tool 102 and/or a plating tool 112 may be used to deposit the sidewall layer 316a and/or the sidewall layer 316b using a CVD technique, a PVD technique, an ALD technique, an electroplating technique, another deposition technique described above in connection with FIG. 1, and/or another suitable deposition technique. The sidewall layer 316a and/or the sidewall layer 316b may be deposited in one or more deposition operations. In some implementations, a seed layer is first deposited, and the sidewall layer 316a and/or the sidewall layer 316b is deposited on the seed layer. In some implementations, a planarization tool 110 may be used to planarize the sidewall layer 316a and/or the sidewall layer 316b after the deposition.

The sidewall layer 316a (and/or the sidewall layer 316b) may include a thickness D3. As an example, the thickness D3 may be included in a range of approximately 50 angstroms to approximately 1000 angstroms. Using sidewall layer 316a as an example, if the thickness D3 is less than approximately 50 angstroms, an effectiveness of the sidewall layer 316a in preventing delamination and/or cracking in the conductive layer 304b, the dielectric layer 306b, the dielectric layer 306c, the conductive layer 304d, and/or the dielectric layer 306d may be reduced to introduce mechanical defects in the trench capacitor structure 220. If the thickness D3 is in the range from approximately 50 angstroms to approximately 1000 angstroms, the sidewall layer 316a may prevent such delamination and/or cracking, and a size of the trench capacitor structure 220 may satisfy a layout threshold (e.g., a size requirement). If the thickness D3 is greater than approximately 1000 angstroms, the size of the trench capacitor structure 220 may not satisfy the layout threshold. However, other values and ranges for the thickness D3 are within the scope of the present disclosure.

As shown in FIG. 4G, and as part of implementation 400, the interconnect structure 234a is formed and the interconnect structure 234b is formed. A deposition tool 102 may and/or a plating tool 112 may be used to deposit the interconnect structure 234a (e.g., over and/or on the sidewall layer 316a in the cavity 410a) using a PVD technique, an ALD technique, a CVD technique, an electroplating technique, an oxidation technique, another type of deposition technique described in connection with FIG. 1, and/or another suitable deposition technique. Additionally, or alternatively, a deposition tool 102 and/or a plating tool 112 may be used to deposit the interconnect structure 234b (e.g., over and/or on the sidewall layer 316b in the cavity 410b) using a PVD technique, an ALD technique, a CVD technique, an electroplating technique, an oxidation technique, another type of deposition technique described in connection with FIG. 1, and/or another suitable deposition technique. The interconnect structure 234a and/or the interconnect structure 234b may be deposited in one or more deposition operations. In some implementations, a planarization tool 110 may be used to planarize the interconnect structure 234a and/or the interconnect structure 234b after deposition.

Upon formation of the interconnect structure 234a, the multi-electrode connection 318a electrically couples multiple capacitor electrode layers (e.g., the conductive layer 304b and the conductive layer 304d) with the sidewall layer 316a and the interconnect structure 234a. Further, and upon formation of the interconnect structure 234b, the multi-electrode connection 318b electrically couples multiple capacitor layers (e.g., the conductive layer 304a and the conductive layer 304c) with the sidewall layer 316b, the interconnect structure 234b, and the substrate of the device region 214.

As further shown in FIG. 4G, the dielectric layer 312 and the dielectric layer 314 are formed over and/or on the dielectric layer(s) 228. A deposition tool 102 may be used to deposit the dielectric layer 312 and/or the dielectric layer 314 using a PVD technique, an ALD technique, a CVD technique, an oxidation technique, another type of deposition technique described in connection with FIG. 1, and/or another suitable deposition technique. The dielectric layer 312 and/or the dielectric layer 314 may be deposited in one or more deposition operations. In some implementations, a planarization tool 110 may be used to planarize the dielectric layer 312 and/or the dielectric layer 314 after deposition.

Furthermore, and as shown in FIG. 4G, the metallization layer 230a and the metallization layer 230b are formed. In some implementations, and as part of forming the metallization layers 230a and 230b, a pattern in a photoresist layer is used to etch the dielectric layers 314 and 312 to form cavities in the dielectric layers 314 and 312. In these implementations, the deposition tool 102 may be used to form the photoresist layer on the dielectric layer 314. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layers 314 and 312 based on the pattern to form the cavities in the dielectric layers 314 and 312. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layers 314 and 312 based on a pattern.

After formation of the cavities, a deposition tool 102 and/or a plating tool 112 may be used to deposit the metallization layer 230a and/or the metallization layer 230b using a CVD technique, a PVD technique, an ALD technique, an electroplating technique, another deposition technique described above in connection with FIG. 1, and/or another suitable deposition technique. The metallization layer 230a and/or the metallization layer 230b may be deposited in one or more deposition operations. In some implementations, a seed layer is first deposited, and the metallization layer 230a and/or the metallization layer 230b is deposited on the seed layer. In some implementations, a planarization tool 110 may be used to planarize the metallization layer 230a and/or the metallization layer 230b after deposition.

As indicated above, FIGS. 4A-4G are provided as an example. Other examples may differ from what is described with regard to FIGS. 4A-4G.

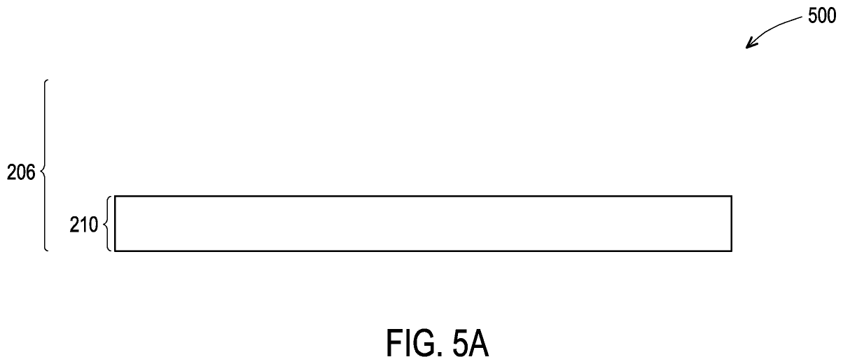

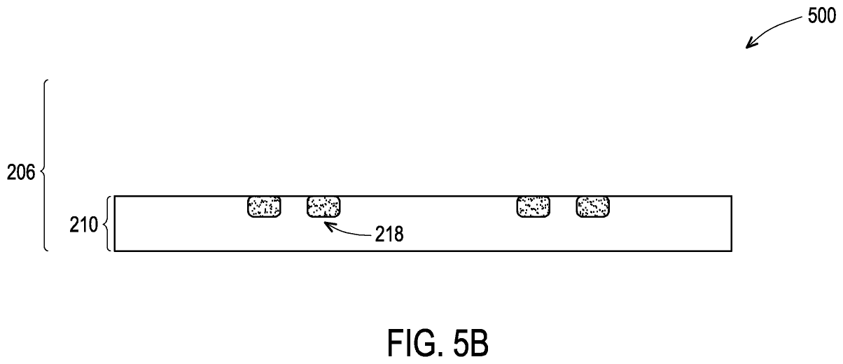

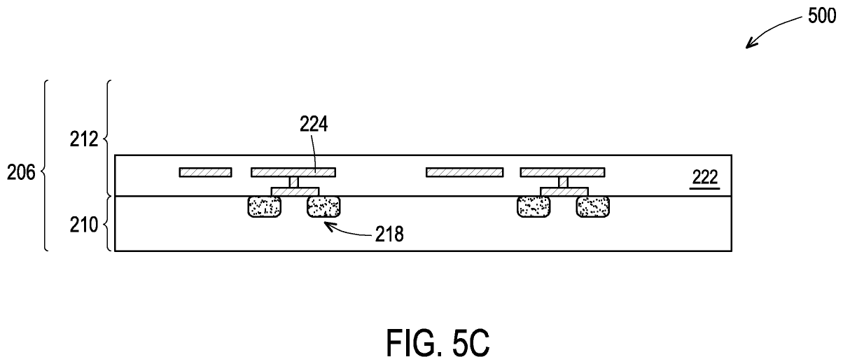

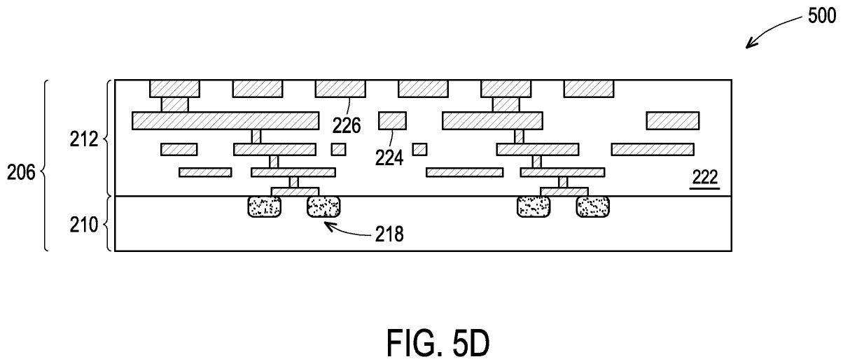

FIGS. 5A-5D are diagrams of an example implementation 500 of forming a semiconductor die described herein. In some implementations, the example implementation 500 includes an example process for forming a portion of the second semiconductor die 206. In some implementations, one or more of the semiconductor processing tools 102-114 and/or the wafer/die transport tool 116 may be used to perform one or more of the operations described in connection with the example implementation 500. In some implementations, one or more operations described in connection with the example implementation 500 may be performed by another semiconductor processing tool.

Turning to FIG. 5A, one or more of the operations in the example implementation 500 may be performed in connection with the semiconductor substrate of the device region 210 of the second semiconductor die 206. The semiconductor substrate of the device region 210 may be provided in the form of a semiconductor wafer or another type of substrate.

As shown in FIG. 5B, one or more semiconductor devices 218 may be formed in the device region 210. For example, one or more of the semiconductor processing tools 102-114 may be used to perform photolithography patterning operations, etching operations, deposition operations, CMP operations, and/or another type of operations to form one or more transistors, one or more capacitors, one or more memory cells, one or more circuits (e.g., one or more ICs), and/or one or more semiconductor devices of another type. In some implementations, one or more regions of the semiconductor substrate of the device region 210 may be doped in an ion implantation operation to form one or more p-wells, one or more n-wells, and/or one or more deep n-wells. In some implementations, the deposition tool 102 may be used to deposit one or more source/drain regions, one or more gate structures, and/or one or more STI regions, among other examples.

As shown in FIG. 5C, a portion of the interconnect region 212 of the second semiconductor die 206 may be formed over and/or on the semiconductor substrate of the device region 210. One or more of the semiconductor processing tools 102-114 may form the interconnect region 212 by forming the dielectric layer(s) 222 and forming a plurality of metallization layer(s) 224 in the dielectric layer(s) 222. For example, the deposition tool 102 may be used to deposit a first layer of the dielectric layer(s) 222 (e.g., using a CVD technique, an ALD technique, a PVD technique, and/or another type of deposition technique), the etch tool 108 may be used to remove portions of the first layer to form recesses in the first layer, and the deposition tool 102 and/or the plating tool 112 may form a first metallization layer of the plurality of metallization layer(s) 224 in the recesses (e.g., using a CVD technique, an ALD technique, a PVD technique, an electroplating technique, and/or another type of deposition technique). At least a portion of the first metallization layer may be electrically connected and/or physically connected with the semiconductor device(s) 218. The deposition tool 102, the etch tool 108, the plating tool 112, and/or another semiconductor processing tool may continue to perform similar processing operations to forming the interconnect region 212 until a sufficient or desired arrangement of metallization layer(s) 224 is achieved.

As shown in FIG. 5D, one or more of the semiconductor processing tools 102-114 may form another layer of the dielectric layer(s) 222, and may form one or more contacts 226 in the layer such that the contact(s) 226 are electrically connected and/or physically connected with one or more of the metallization layer(s) 224. For example, the deposition tool 102 may be used to deposit the layer of the dielectric layer(s) 222 (e.g., using a CVD technique, an ALD technique, a PVD technique, and/or another type of deposition technique), the etch tool 108 may be used to remove portions of the layer to form recesses in the layer, and the deposition tool 102 and/or the plating tool 112 may form the contact(s) 226 in the recesses (e.g., using a CVD technique, an ALD technique, a PVD technique, an electroplating technique, and/or another type of deposition technique).

As indicated above, FIGS. 5A-5D are provided as an example. Other examples may differ from what is described with regard to FIGS. 5A-5D.

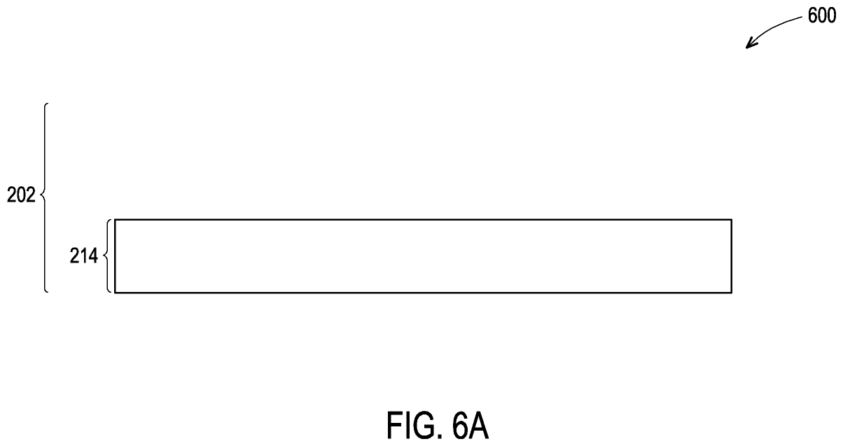

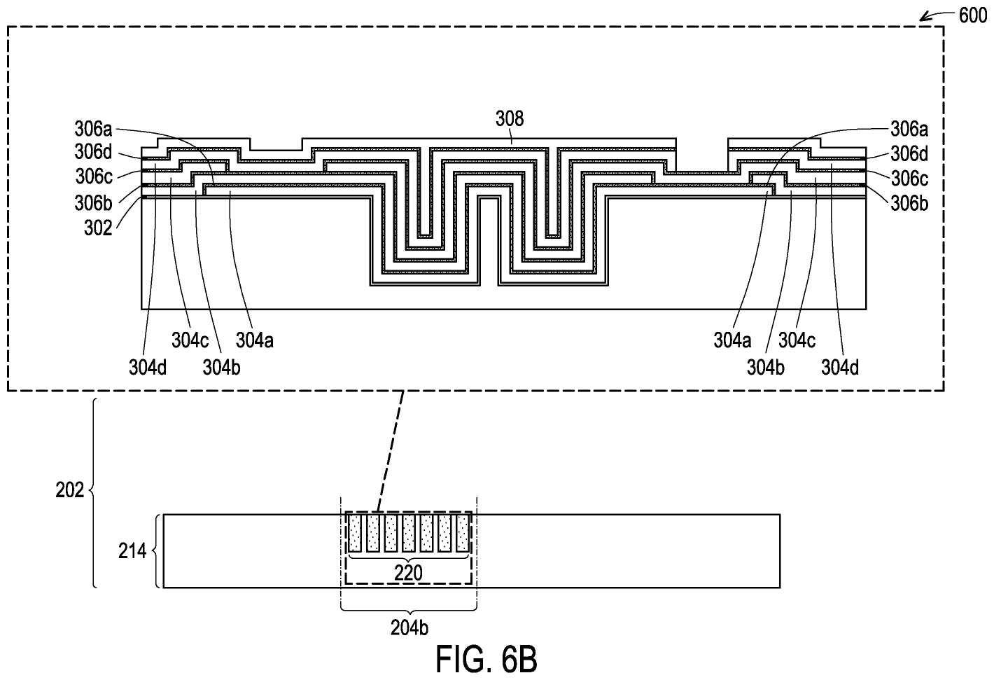

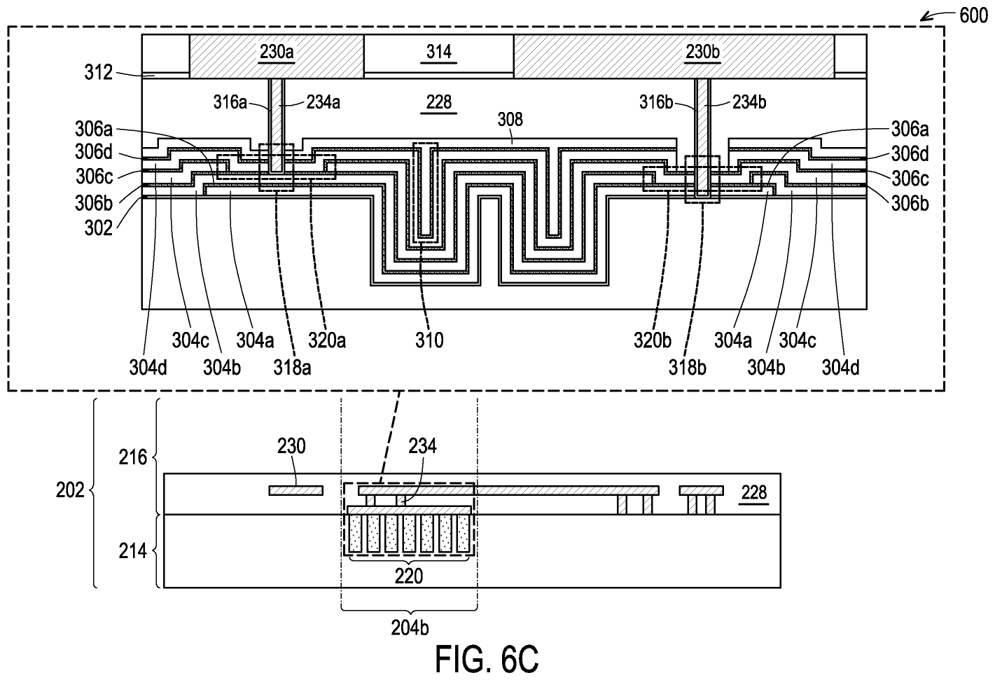

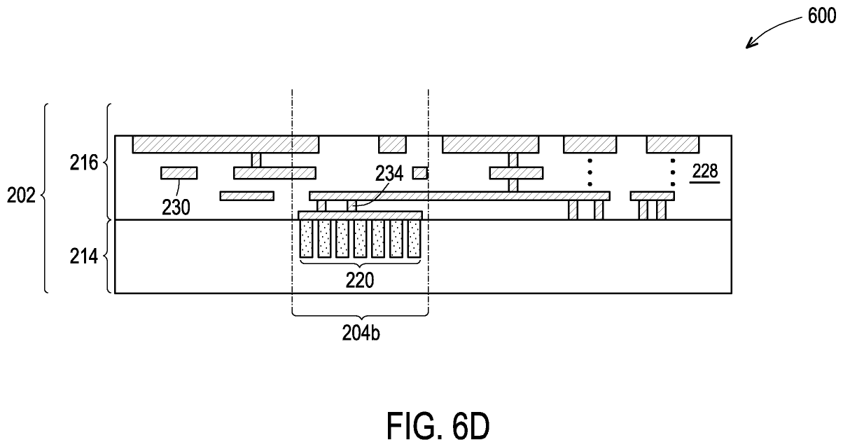

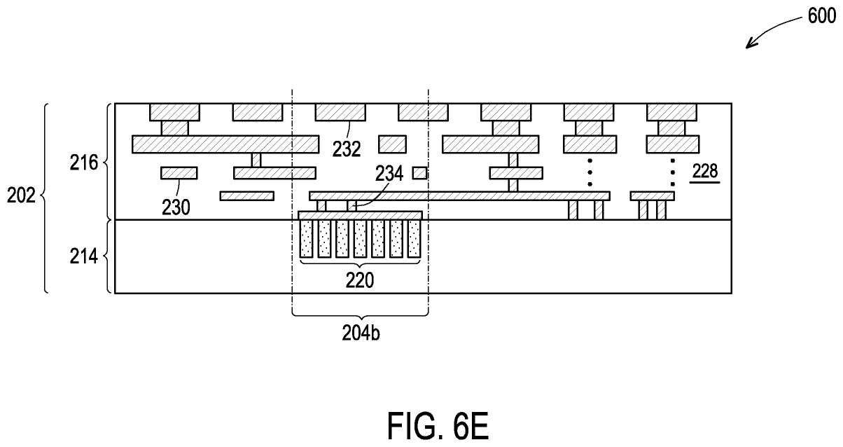

FIGS. 6A-6E are diagrams of an example implementation 600 of forming a semiconductor die described herein. In some implementations, the example implementation 600 includes an example process for forming a portion of the first semiconductor die 202. In some implementations, one or more of the semiconductor processing tools 102-114 and/or the wafer/die transport tool 116 may be used to perform one or more of the operations described in connection with the example implementation 600. In some implementations, one or more operations described in connection with the example implementation 600 may be performed by another semiconductor processing tool.

Turning to FIG. 6A, one or more of the operations in the example implementation 600 may be performed in connection with the semiconductor substrate of the device region 214 of the first semiconductor die 202. The semiconductor substrate of the device region 214 may be provided in the form of a semiconductor wafer or another type of substrate.

As shown in FIG. 6B, the trench capacitor structure 220 may be formed in the device region 214. Using techniques described in connection with FIGS. 4A-4E and elsewhere herein, the one or more semiconductor processing tools 102-114 may form the trench capacitor structure 220, including the liner layer 302, the conductive layers 304a-304b, the dielectric layers 306a-306d, and the dielectric layer 308.

As shown in FIG. 6C, a portion of the interconnect region 216 of the first semiconductor die 202 may be formed over and/or on the semiconductor substrate of the device region 214. Using techniques described in connection with FIGS. 4F, 4G, and elsewhere herein, the one or more semiconductor processing tools 102-114 may form the interconnect structure 234a, the interconnect structure 234b, the sidewall layer 316a, the sidewall layer 316b, the metallization layer 230a, the metallization layer 230b, the multi-electrode connection 318a, and/or the multi-electrode connection 318b.

As shown in FIG. 6D, the deposition tool 102, the etch tool 108, the plating tool 112, and/or another semiconductor processing tool may continue to perform similar processing operations to continue forming the dielectric layer(s) 228 and/or the metallization layer(s) 230 in the interconnect region 216.

As shown in FIG. 6E, one or more of the semiconductor processing tools 102-114 may be used to form another layer of the dielectric layer(s) 228, and may be used to form one or more contacts 232 in the layer such that the contact(s) 232 are electrically connected and/or physically connected with one or more of the metallization layer(s) 230. For example, the deposition tool 102 may be used to deposit the layer of the dielectric layer(s) 228 (e.g., using a CVD technique, an ALD technique, a PVD technique, and/or another type of deposition technique), the etch tool 108 may be used to remove portions of the layer to form recesses in the layer, and the deposition tool 102 and/or the plating tool 112 may be used to form the contact(s) 232 in the recesses (e.g., using a CVD technique, an ALD technique, a PVD technique, an electroplating technique, and/or another type of deposition technique).

As indicated above, FIGS. 6A-6E are provided as an example. Other examples may differ from what is described with regard to FIGS. 6A-6E.

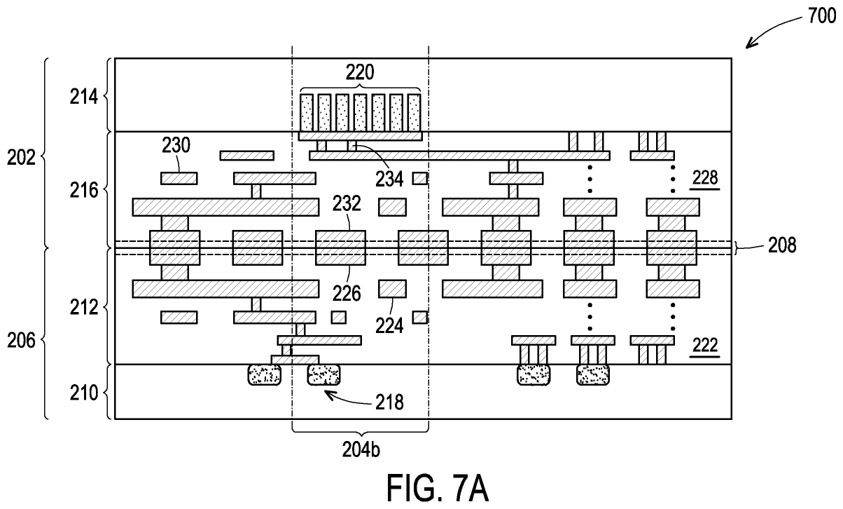

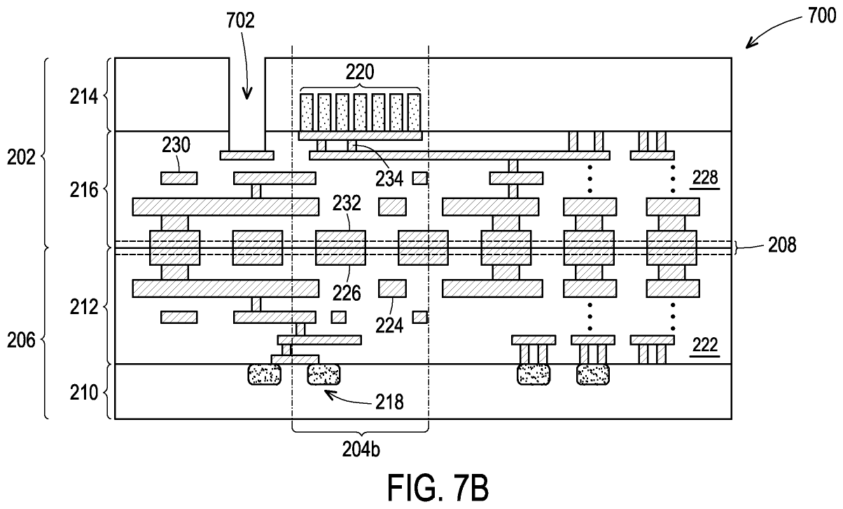

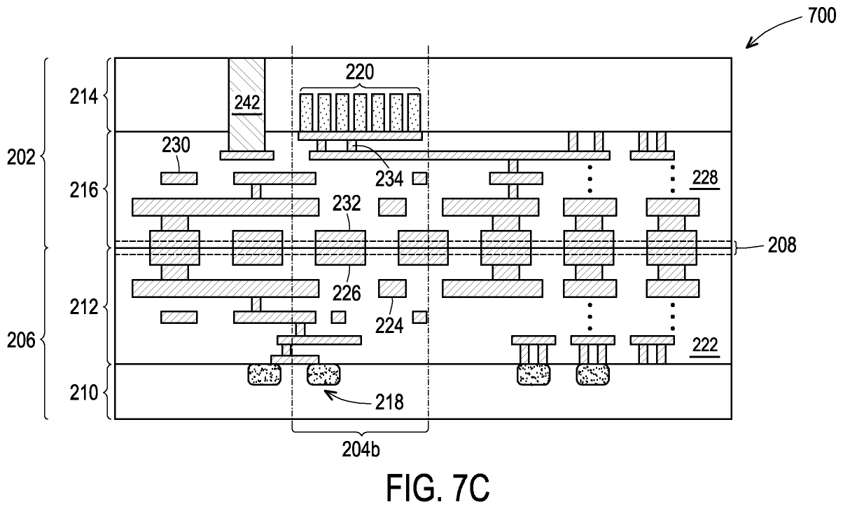

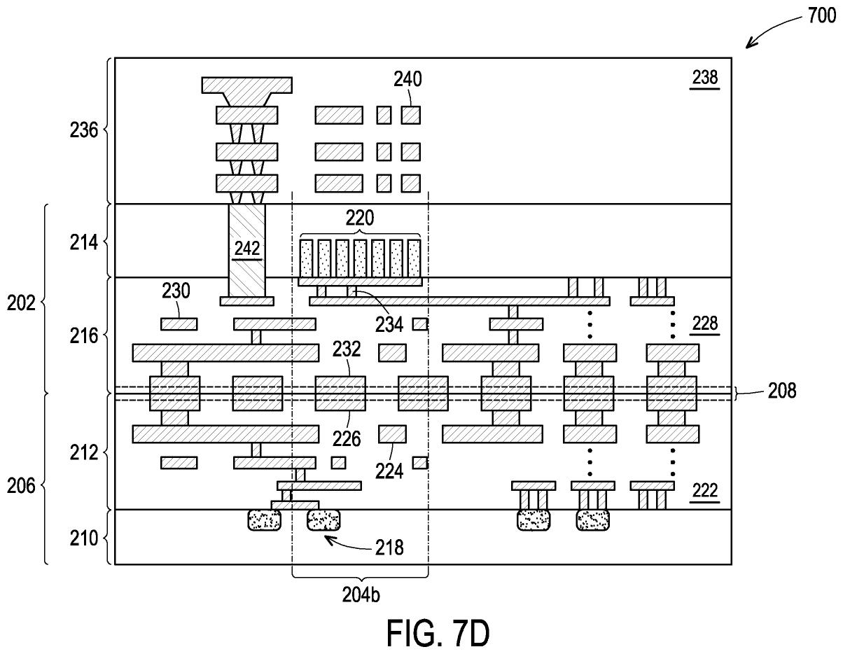

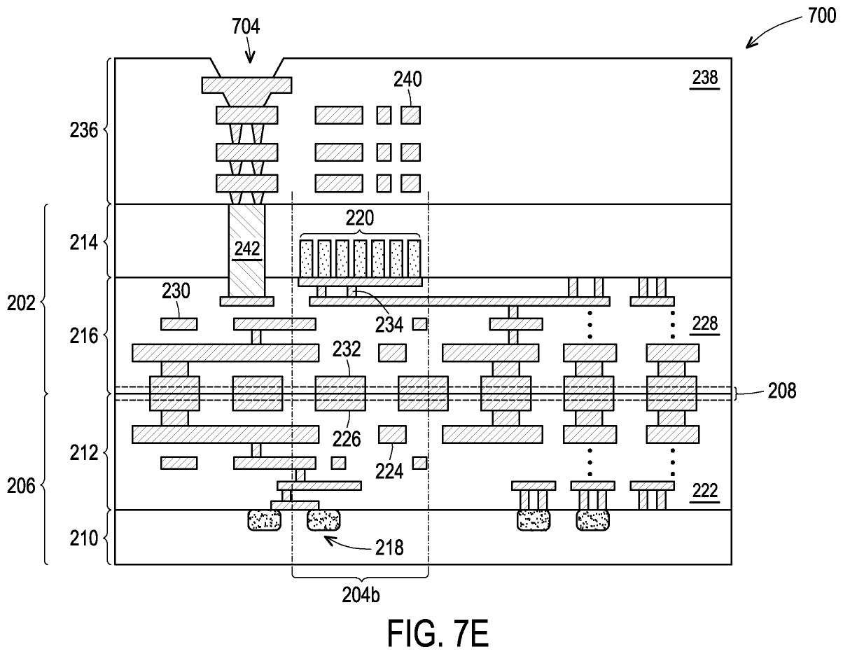

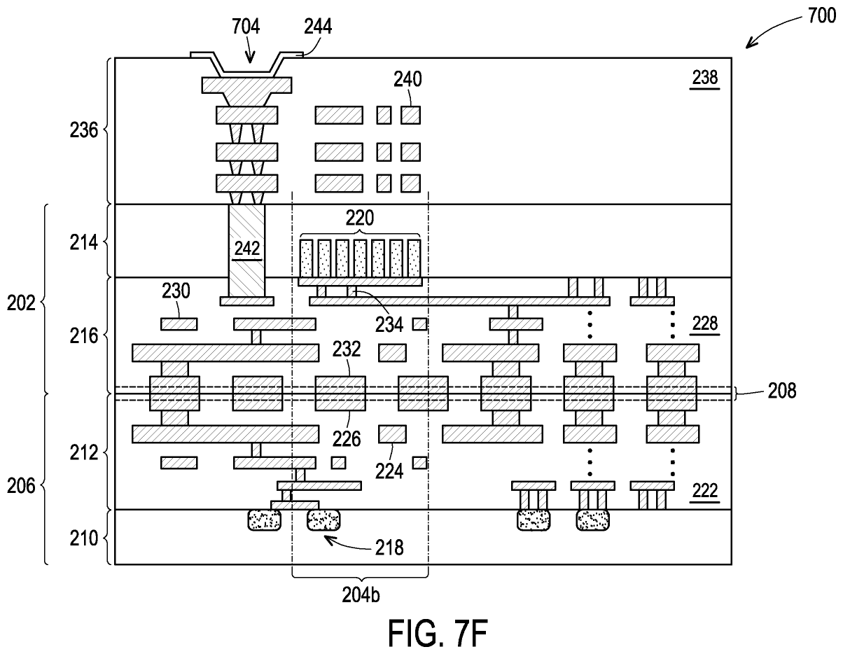

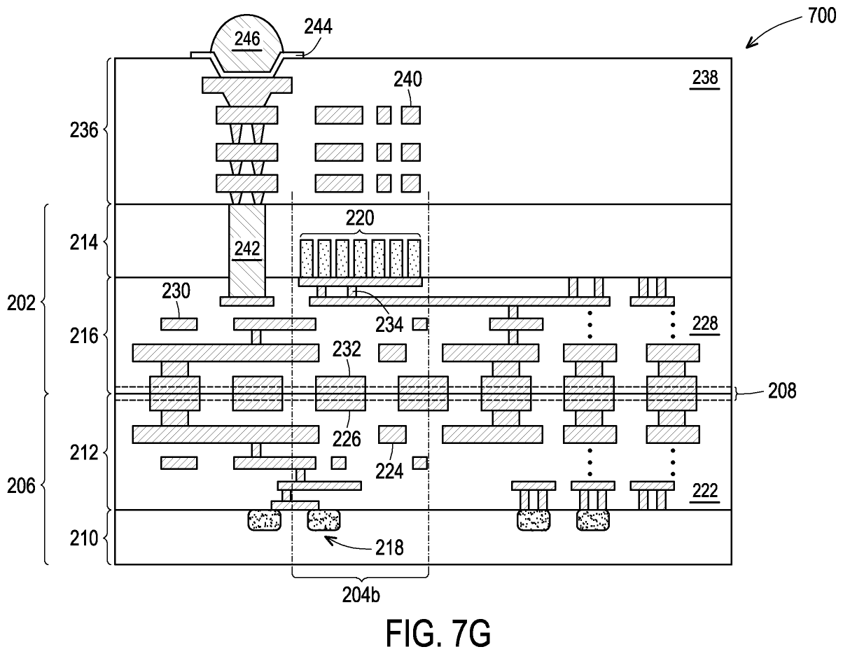

FIGS. 7A-7G are diagrams of an example implementation 700 of forming a portion of a semiconductor die package 200 described herein. In some implementations, one or more operations described in connection with FIGS. 7A-7G may be performed by one or more of the semiconductor processing tools 102-114 and/or the wafer/die transport tool 116. In some implementations, one or more operations described in connection with FIGS. 7A-7G may be performed by another semiconductor processing tool.

As shown in FIG. 7A, the first semiconductor die 202 and the second semiconductor die 206 may be bonded at the bonding interface 208 such that the first semiconductor die 202 and the second semiconductor die 206 are vertically arranged or stacked. The first semiconductor die 202 and the second semiconductor die 206 may be vertically arranged or stacked in a WoW configuration, a die on wafer configuration, a die on die configuration, and/or another direct bonding configuration. The bonding tool 114 may be used to perform a bonding operation to bond the first semiconductor die 202 and the second semiconductor die 206 at the bonding interface 208. The bonding operation may include a direct bonding operation in which bonding of first semiconductor die 202 and the second semiconductor die 206 is achieved through the physical connection of the contact(s) 226 with the contact(s) 232. At the bonding interface 208, a direct metal bonding is formed between the contact(s) 226/232, and a direct dielectric bond is formed between two dielectric layers.

As shown in FIG. 7B, one or more recesses 702 may be formed through the semiconductor substrate of the device region 214 and into a portion of the dielectric layer(s) 228 of the interconnect region 216. The recess(es) 702 may be formed to expose one or more portions of a metallization layer 230 in the interconnection region 216. Thus, the recess(es) 702 may be formed over the one or more portions of a metallization layer 230.

In some implementations, a pattern in a photoresist layer is used to form the recess(es) 702. In these implementations, the deposition tool 102 forms the photoresist layer over the silicon substrate of the device region 214. The exposure tool 104 exposes the photoresist layer to a radiation source to pattern the photoresist layer. The developer tool 106 develops and removes portions of the photoresist layer to expose the pattern. The etch tool 108 etches through the semiconductor substrate of the device region 214 and into a portion of the dielectric layer(s) 228 of the interconnect region 216 to form the recess(es) 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess(es) 702 based on a pattern.

As shown in FIG. 7C, the BTSV structure(s) 242 may be formed in the recess(es) 702. In this way, the BTSV structure(s) 242 extend through the semiconductor substrate the device region 214 and into the interconnect region 216. The BTSV structure(s) 242 may be electrically connected and/or physically connected with the one or more portions of the metallization layer 230 that were exposed through the recess(es) 702.

The deposition tool 102 and/or the plating tool 112 may be used to deposit the BTSV structure(s) 242 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may be used to perform a CMP operation to planarize the BTSV structure(s) 242 after the BTSV structure(s) 242 are deposited.

As shown in FIG. 7D, the redistribution structure 236 of the semiconductor die package 200 may be formed over the first semiconductor die 202. One or more of the semiconductor processing tools 102-114 may be used to form the redistribution structure 236 by forming one or more dielectric layers 238 and forming a plurality of metallization layers 240 in the plurality of dielectric layers 238. For example, the deposition tool 102 may be used to deposit a first layer of the one or more dielectric layers 238 (e.g., using a CVD technique, an ALD technique, a PVD technique, and/or another type of deposition technique), the etch tool 108 may be used to remove portions of the first layer to form recesses in the first layer, and the deposition tool 102 and/or the plating tool 112 may be used to form a first metallization layer of the plurality of metallization layers 240 in the recesses (e.g., using a CVD technique, an ALD technique, a PVD technique, an electroplating technique, and/or another type of deposition technique). At least a portion of the first metallization layer may be electrically connected and/or physically connected with the BTSV structure(s) 242. The deposition tool 102, the etch tool 108, the plating tool 112, and/or another semiconductor processing tool may continue to perform similar processing operations to forming the redistribution structure 236 until a sufficient or desired arrangement of metallization layers 240 is achieved.

As shown in FIG. 7E, recesses 704 may be formed in the one or more dielectric layers 238. The recesses 704 may be formed to expose portions of a metallization layer 240 in the redistribution structure 236. Thus, the recesses 704 may be formed over the one or more portions of a metallization layer 240.

In some implementations, a pattern in a photoresist layer is used to form the recesses 702. In these implementations, the deposition tool 102 forms the photoresist layer on the one or more dielectric layers 238. The exposure tool 104 exposes the photoresist layer to a radiation source to pattern the photoresist layer. The developer tool 106 develops and removes portions of the photoresist layer to expose the pattern. The etch tool 108 etches into the one or more dielectric layers 238 to form the recesses 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 704 based on a pattern.

As shown in FIG. 7F, UBM layers 244 may be formed in the recesses 704. The deposition tool 102 and/or the plating tool 112 may be used to deposit the UBM layers 244 using a CVD technique, a PVD technique, an ALD technique, an electroplating technique, another deposition technique described above in connection with FIG. 1, and/or a deposition technique other than as described above in connection with FIG. 1. In some implementations, a continuous layer of conductive material is deposited on the top surface of the redistribution structure 236, including in the recess 702. The continuous layer of conductive material is then patterned (e.g., by the deposition tool 102, the exposure tool 104, and the developer tool 106) to form a pattern on the continuous layer of the conductive material, and the etch tool 108 removes portions of the continuous layer of the conductive material based on the pattern. Remaining portions of the continuous layer of the conductive material may correspond to the UBM layers 244.

As shown in FIG. 7G, conductive terminals 246 may be formed in the recesses 704 over the UBM layers 244. In some implementations, the plating tool 112 forms the conductive terminals 246 using an electroplating technique. In some implementations, solder is dispensed in the recesses 704 to form the conductive terminals 246.

As indicated above, FIGS. 7A-7G are provided as an example. Other examples may differ from what is described with regard to FIGS. 7A-7G.

FIGS. 8A and 8B are diagrams related to vertical interconnect access induced metal island corrosion defects described herein. FIG. 8A shows an example electrical circuit 802 including the trench capacitor structure 220, the conductive layer 304a, the conductive layer 304b, the conductive layer 304c, the conductive layer 304d, and the interconnect structure 234b that connects with the substrate of the device region 214. As shown, and during formation of the trench capacitor structure 220, the conductive layer 304a and/or the conductive layer 304c (e.g., negative (−) polarity capacitor electrode layers) may be exposed to an electrical potential 804. Additionally, or alternatively and during formation of the trench capacitor structure 220, the conductive layer 304b and/or the conductive layer 304d (e.g., positive (+) polarity capacitor electrode layers) may be exposed to an electrical potential 806.

In some implementations, and during a cleaning operation (e.g., a wet clean operation that may be used in conjunction with an etching operation described in connections with FIGS. 4A-4G), the trench capacitor structure 220 may accumulate an electrical potential 808. Based on the interconnect structure 234b that electrically couples the electrical circuit 802 to the substrate of the device region 214, a voltage drop 810 may occur that inhibits a discharge of the electrical potential 808 from the trench capacitor structure 220 into the conductive layers 304a-304d. By inhibiting the discharge of the electrical potential 808, a superposition of electrical potentials (e.g., the electrical potential 808 combining with the electrical potential 804 and/or the electrical potential 806) may be avoided to reduce a likelihood of damage to one or more features of the trench capacitor structure 220. Within the electrical circuit 802, the voltage drop 810 may correspond to a voltage divider effect that complies with Kirchhoff's law.

FIG. 8B shows an example comparison of defect distributions across a wafer-based substrate. In FIG. 8B, example 812 may correspond to a wafer-based substrate (e.g., a silicon semiconductor wafer) including multiples of a semiconductor die that does not include configurations of the multi-electrode connection 318a and/or the multi-electrode connection 318b described herein. In contrast, example 814 may correspond to a wafer-based substrate including multiples of a semiconductor die that includes configurations of the multi-electrode connection 318a and/or the multi-electrode connection 318b.

In some implementations, and as shown in example 812, a defect density may increase near a perimeter of the wafer-based substrate due to electrical potentials within trench capacitors near the perimeter (e.g. the trench capacitor structure(s) 220) that increase during a wet clean operation (e.g., during a wet clean operation that includes a spinning of the wafer-based substrate, where a localized velocity near a perimeter may be greater relative to a localized velocity near a center and cause additional charge buildups within the trench capacitor structure(s) 220 near the perimeter). However, and as shown in example 814, a defect distribution (e.g., an amount of vertical interconnect access induced metal island corrosion (VIMIC) defects across the wafer-based substrate and/or a defect density near a perimeter of the wafer-based substrate) is substantially lesser relative to a defect distribution in the example 812.

As shown in FIG. 8B, a likelihood of VIMIC defects within the wafer-based substrate (e.g., VIMIC defects within semiconductor dies) may decrease due to the semiconductor dies including the multi-electrode connection 318a and/or the multi-electrode connection 318b. By decreasing the likelihood of such defects, a yield of the semiconductor dies may increase to reduce an amount of resources needed to fabricate a volume of the semiconductor dies (e.g., semiconductor manufacturing tools, raw materials, manpower, and/or computing resources).

As indicated above, FIGS. 8A and 8B are provided as examples. Other examples may differ from what is described with regard to FIGS. 8A and 8B.

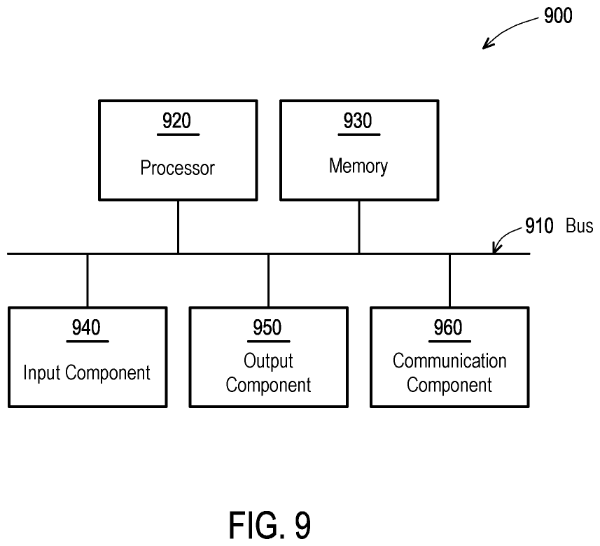

FIG. 9 is a diagram of example components of a device 900 described herein. In some implementations, one or more of the semiconductor processing tools 102-114 and/or the wafer die transport tool 116 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may be used to perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may be used to perform one or more functions described as being performed by another set of components of the device 900.

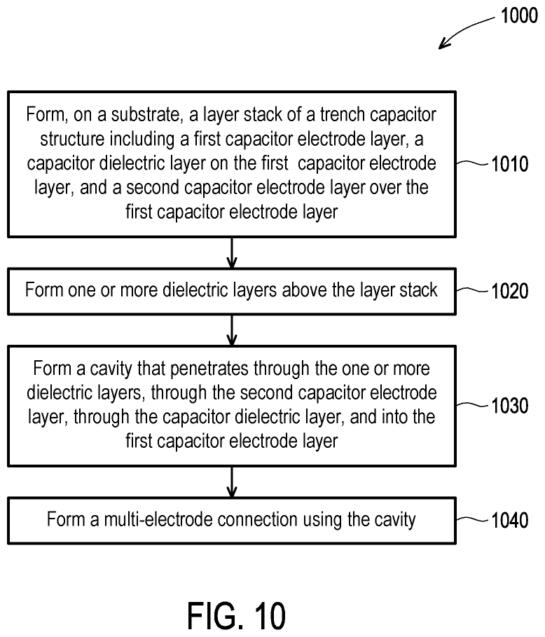

FIG. 10 is a flowchart of an example process 1000 associated with forming a trench capacitor structure described herein. In some implementations, one or more process blocks of FIG. 10 are performed using one or more semiconductor processing tools (e.g., one or more of the semiconductor processing tools 102-114). Additionally, or alternatively, one or more process blocks of FIG. 10 may be performed using one or more components of device 900, such as processor 920, memory 930, input component 940, output component 950, and/or communication component 960.

As shown in FIG. 10, process 1000 may include forming, on a substrate, a layer stack of a trench capacitor structure including a first capacitor electrode layer, a capacitor dielectric layer on the first capacitor electrode layer, and a second capacitor electrode layer over the first capacitor electrode layer (block 1010). For example, one or more of the semiconductor processing tools 102-114 may be used to form, on a substrate (e.g., the substrate of the device region 214), a layer stack of a trench capacitor structure (e.g., the trench capacitor structure 220) including a first capacitor electrode layer (e.g., the conductive layer 304b), a capacitor dielectric layer (e.g., the dielectric layer 306b) on the first capacitor electrode layer, and a second capacitor electrode layer (e.g., the conductive layer 304b) over the first capacitor electrode layer, as described herein.

As further shown in FIG. 10, process 1000 may include forming one or more dielectric layers above the layer stack (block 1020). For example, one or more of the semiconductor processing tools 102-114 may be used to form one or more dielectric layers (e.g., the dielectric layer 308, the dielectric layer 312, and or the dielectric layer 314) above the layer stack, as described herein.

As further shown in FIG. 10, process 1000 may include forming a cavity that penetrates through the one or more dielectric layers, through the second capacitor electrode layer, through the capacitor dielectric layer, and into the first capacitor electrode layer (block 1030). For example, one or more of the semiconductor processing tools 102-114 may be used to form a cavity (e.g., the cavity 410a) that penetrates through the one or more dielectric layers, through the second capacitor electrode layer, through the capacitor dielectric layer, and into the first capacitor electrode layer, as described herein.

As further shown in FIG. 10, process 1000 may include forming a multi-electrode connection using the cavity (block 1040). For example, one or more of the semiconductor processing tools 102-114 may be used to form a multi-electrode connection (e.g., the multi-electrode connection 318a) using the cavity, as described herein.

Process 1000 may include additional implementations, such as any single implementation or any combination of implementations described below and/or in connection with one or more other processes described elsewhere herein.

In a first implementation, forming the layer stack further includes forming a third capacitor electrode layer (e.g., the conductive layer 304c) on the capacitor dielectric layer. In some implementations, forming the third capacitor electrode layer includes forming a gap region (e.g., the gap region 320a) in the third capacitor electrode layer over a portion of the first capacitor electrode layer.

In a second implementation, alone or in combination with the first implementation, forming the third capacitor electrode layer includes depositing the third capacitor electrode layer on the capacitor dielectric layer, and removing a portion of the third capacitor electrode layer using etching operation to form a discontinuity in the third capacitor electrode layer that corresponds to the gap region.

In a third implementation, alone or in combination with one or more of the first and second implementations, forming the layer stack includes forming the second capacitor electrode layer using a conformal deposition process that forms a portion of the second capacitor electrode layer in the gap region.

In a fourth implementation, alone or in combination with one or more of the first through third implementations, forming the cavity that penetrates through the one or more dielectric layers, through the second capacitor electrode layer, through the capacitor dielectric layer, and into the first capacitor electrode layer includes forming the cavity through the portion of the second capacitor electrode layer in the gap region.

In a fifth implementation, alone or in combination with one or more of the first through fourth implementations, forming the multi-electrode connection includes forming a sidewall layer (e.g., the sidewall layer 316a) along an interior surface of the cavity.

In a sixth implementation, alone or in combination with one or more of the first through fifth implementations, forming the sidewall layer includes forming the sidewall layer by depositing a conductive material that electrically couples the first capacitor electrode layer and the second capacitor electrode layer.

In a seventh implementation, alone or in combination with one or more of the first through sixth implementations, forming the multi-electrode connection further includes forming an interconnect structure (e.g., the interconnect structure 234a) in the cavity on the sidewall layer.

In an eighth implementation, alone or in combination with one or more of the first through seventh implementations, forming the interconnect structure includes forming the interconnect structure by depositing an electrically conductive material in the cavity on the sidewall layer.

In a ninth implementation, alone or in combination with one or more of the first through eighth implementations, process 1000 includes forming a metallization layer (e.g., the metallization layer(s) 230) over the one or more dielectric layers, and performing a cleaning operation. In some implementations, a likelihood of vertical interconnect access induced metal island corrosion defects induced by the cleaning operation to at least one of the metallization layer, the interconnect structure, the first capacitor electrode layer, or the second capacitor electrode layer is reduced by using the multi-electrode connection to reduce a voltage drop between the metallization layer and the substrate.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

Some implementations described herein provide a semiconductor device including a trench capacitor structure and methods of forming. Using a multi-electrode connection that includes use of a conductive sidewall layer, the interconnect structure may connect with multiple, vertically-arranged electrode layers of the trench capacitor structure. In contrast to connecting with a single electrode layer, connecting with the multiple, vertically-arranged electrode layers may increase an effective thickness of a land for the interconnect structure. The increased effective thickness may increase an etching and cleaning process window to reduce a likelihood of VIMIC defects developing in metal structures of the trench capacitor structure.

In this way, a performance of the trench capacitor structure (e.g., an amount of charge storage and/or a duration of the charge storage) is increased while improving a quality and/or a reliability of the semiconductor device. Additionally, a quantity of interconnect structures for the trench capacitor structure is decreased to reduce a size of the trench capacitor structure (thereby reducing a size of the semiconductor device). By increasing the performance of the trench capacitor structure, improving the yield and/or reliability of the semiconductor device, or reducing the size of the semiconductor device, an amount of resources used to support a market consuming the semiconductor device (e.g., an amount of semiconductor processing tools, labor, raw materials, and/or computing resources) may be reduced.

As described in greater detail above, some implementations described herein provide a structure. The structure includes a first conductive layer. The structure includes a dielectric layer on the first conductive layer. The structure includes a second conductive layer on the dielectric layer having a gap region over a portion of the first conductive layer. The structure includes a third conductive layer including a portion in the gap region. The structure includes an interconnect structure penetrating through the portion of the third conductive layer in the gap region, through the dielectric layer, and into the first conductive layer. The structure includes a sidewall layer surrounding the interconnect structure and penetrating through the portion of the third conductive layer in the gap region, through the dielectric layer, and into the first conductive layer.

As described in greater detail above, some implementations described herein provide a semiconductor device. The semiconductor device includes a metallization layer that includes first portion a second portion. The semiconductor device includes a trench capacitor structure that includes at least two vertically-arranged positive polarity capacitor electrode layers and at least two vertically-arranged negative polarity capacitor electrode layers. The semiconductor device includes a first interconnect structure connecting the at least two vertically-arranged positive polarity capacitor electrode layers with the first portion. The semiconductor device includes a second interconnect structure connecting the at least two vertically-arranged negative polarity capacitor electrode layers with the second portion.

As described in greater detail above, some implementations described herein provide a method. The method includes forming, on a substrate, a layer stack of a trench capacitor structure including a first capacitor electrode layer, a capacitor dielectric layer on the first capacitor electrode layer, and a second capacitor electrode layer over the first capacitor electrode layer. The method includes forming one or more dielectric layers above the layer stack. The method includes forming a cavity that penetrates through the one or more dielectric layers, through the second capacitor electrode layer, through the capacitor dielectric layer, and into the first capacitor electrode layer. The method includes forming a multi-electrode connection using the cavity.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a first conductive layer;
a dielectric layer on the first conductive layer;
a second conductive layer on the dielectric layer having a gap region over a portion of the first conductive layer;
a third conductive layer including a portion in the gap region;
an interconnect structure penetrating through the portion of the third conductive layer in the gap region, through the dielectric layer, and into the first conductive layer; and
a sidewall layer surrounding the interconnect structure and penetrating through the portion of the third conductive layer in the gap region, through the dielectric layer, and into the first conductive layer.

2. The structure of claim 1, wherein the sidewall layer comprises a conductive material that electrically couples the interconnect structure with the first conductive layer and the third conductive layer.

3. The structure of claim 1, wherein a thickness of the first conductive layer and the second conductive layer are included in a range of approximately 100 angstroms to approximately 200 angstroms.

4. The structure of claim 1, wherein a thickness of the sidewall layer is included in a range of approximately 50 angstroms to approximately 1000 angstroms.

5. The structure of claim 1, wherein the dielectric layer is a first dielectric layer and the structure further comprises:
a second dielectric layer on the second conductive layer,
wherein the second dielectric layer conforms to edges of the second conductive layer that define the gap region to electrically isolate the second conductive layer from the third conductive layer, the interconnect structure, and the sidewall layer.

6. The structure of claim 5, wherein the second dielectric layer merges with the first dielectric layer below the gap region.

7. A semiconductor device, comprising:
a metallization layer comprising:
a first portion; and
a second portion;
a trench capacitor structure, comprising:
at least two vertically-arranged positive polarity capacitor electrode layers; and
at least two vertically-arranged negative polarity capacitor electrode layers;
a first interconnect structure connecting the at least two vertically-arranged positive polarity capacitor electrode layers with the first portion; and
a second interconnect structure connecting the at least two vertically-arranged negative polarity capacitor electrode layers with the second portion.

8. The semiconductor device of claim 7, wherein the trench capacitor structure further comprises:
a dielectric layer that merges in a vertically-oriented merge region between co-facing surfaces of a top layer of the trench capacitor structure,
wherein the first interconnect structure penetrates through the dielectric layer above the at least two vertically-arranged positive polarity capacitor electrode layers.

9. The semiconductor device of claim 7, wherein the trench capacitor structure further comprises:
a dielectric layer that merges in a vertically-oriented merge region between co-facing surfaces of a top capacitor electrode layer of the trench capacitor structure, and
wherein the second interconnect structure penetrates through a gap region in the dielectric layer that is above the at least two vertically-arranged negative polarity capacitor electrode layers.

10. The semiconductor device of claim 7, wherein the second interconnect structure passes through the at least two vertically-arranged negative polarity capacitor electrode layers to a substrate below the at least two vertically-arranged negative polarity capacitor electrode layers.

11. A method, comprising:
forming, on a substrate, a layer stack of a trench capacitor structure including a first capacitor electrode layer, a capacitor dielectric layer on the first capacitor electrode layer, and a second capacitor electrode layer over the first capacitor electrode layer;
forming one or more dielectric layers above the layer stack;
forming a cavity that penetrates through the one or more dielectric layers, through the second capacitor electrode layer, through the capacitor dielectric layer, and into the first capacitor electrode layer; and
forming a multi-electrode connection using the cavity.

12. The method of claim 11, wherein forming the layer stack further includes:
forming a third capacitor electrode layer on the capacitor dielectric layer,
wherein forming the third capacitor electrode layer includes forming a gap region in the third capacitor electrode layer over a portion of the first capacitor electrode layer.

13. The method of claim 12, wherein forming the third capacitor electrode layer includes:
depositing the third capacitor electrode layer on the capacitor dielectric layer; and
removing a portion of the third capacitor electrode layer using etching operation to form a discontinuity in the third capacitor electrode layer that corresponds to the gap region.

14. The method of claim 13, wherein forming the layer stack includes:
forming the second capacitor electrode layer using a conformal deposition process that forms a portion of the second capacitor electrode layer in the gap region.

15. The method of claim 14, wherein forming the cavity that penetrates through the one or more dielectric layers, through the second capacitor electrode layer, through the capacitor dielectric layer, and into the first capacitor electrode layer includes:
forming the cavity through the portion of the second capacitor electrode layer in the gap region.

16. The method of claim 11, wherein forming the multi-electrode connection includes:
forming a sidewall layer along an interior surface of the cavity.

17. The method of claim 16, wherein forming the sidewall layer includes:
forming the sidewall layer by depositing a conductive material that electrically couples the first capacitor electrode layer and the second capacitor electrode layer.

18. The method of claim 16, wherein forming the multi-electrode connection further includes:
forming an interconnect structure in the cavity on the sidewall layer.

19. The method of claim 18, wherein forming the interconnect structure includes:
forming the interconnect structure by depositing an electrically conductive material in the cavity on the sidewall layer.

20. The method of claim 18, further comprising:
forming a metallization layer over the one or more dielectric layers; and
performing a cleaning operation,
wherein a likelihood of vertical interconnect access induced metal island corrosion defects induced by the cleaning operation to at least one of the metallization layer, the interconnect structure, the first capacitor electrode layer, or the second capacitor electrode layer is reduced by using the multi-electrode connection to reduce a voltage drop between the metallization layer and the substrate.
